(19) United States
(12) Patent Application Publication
(10) Pub. No.: US 2015/0279909 A1
(43) Pub. Date: Oct. 1, 2015

(54) ORGANIC ELECTROLUMINESCENCE ELEMENT AND ILLUMINATION DEVICE

(71) Applicant: Panasonic Intellectual Property Management Co., Ltd., Osaka-shi, Osaka (JP)

(72) Inventors: Hiroya Tsuji, Kyoto (JP); Satoshi Ohara, Tokyo (JP); Varutt Kittichungchit, Osaka (JP)

(73) Assignee: PANASONIC INTELLECTUAL PROPERTY MANAGEMENT CO., LTD., Osaka-shi, Osaka (JP)

(21) Appl. No.: 14/437,517

(22) PCT Filed: Oct. 30, 2013
(86) PCT No.: PCT/JP2013/006419

§ 371 Date: Apr. 22, 2015

(30) Foreign Application Priority Data
Oct. 31, 2012 (JP) 2012-240816

(51) Int. Cl. H01L 27/32; H01L 51/52; H01L 51/50

(52) U.S. Cl. CPC H01L 27/3209; H01L 51/504; H01L 51/5218; H01L 51/5221; H01L 2251/5376

(57) ABSTRACT

An organic electroluminescence element has a multi-unit structure which includes a first light-emitting unit, an intermediate layer and a second light-emitting unit. A light-emitting layer of the first light-emitting unit includes a blue light-emitting material. The second light-emitting unit has a stacked structure of light-emitting layers in which a red light-emitting layer including a red light-emitting material and a green light-emitting layer including a green light-emitting material are stacked. One of the red light-emitting layer and the green light-emitting layer is closer to the positive electrode than the other of the red light-emitting layer and the green light-emitting layer, and includes a hole-transporting material as a host material. The other of the red light-emitting layer and the green light-emitting layer is closer to the negative electrode than the one of the red light-emitting layer and the green light-emitting layer, and includes an electron-transporting material as a host material.

### TECHNICAL FIELD

The present invention relates to an organic electroluminescence element and an illumination device including the same.

### BACKGROUND ART

An organic electroluminescence element (hereinafter, referred also to as “an organic EL element”) has attracted attention as a next-generation illumination light source because it enables planar emission and an extremely reduction in a thickness, and has been vigorously developed with the aim of practical use. These days, an illumination device achieving emission at various color temperatures required for an illumination light source by selecting a light-emitting material and adjusting a stacked structure has been developed at an accelerated rate. For example, white emission being closer to an intended hue can be obtained by using a plurality of kinds of light-emitting materials. In order to bring the emission closer to intended white, there has been also developed an element having a multi-unit structure in which a plurality of light-emitting units are stacked with an intermediate layer interposed between two adjacent light-emitting units of the light-emitting units.

However, in the organic EL element, a change in an emission color is very sensitive to a change in a film thickness and a change in an amount of a light-emitting material to be mixed. Problems still remain in order to achieve a white organic EL element for illumination having a small chromaticity change.

### PRIOR ART DOCUMENTS

### Patent Literature

Patent literature 1: JP-2005-267990 A

Patent literature 2: JP-2011-70963 A

### SUMMARY OF THE INVENTION

### Problems to be Resolved by the Invention

Patent Literature 1 (JP-2005-267990 A) proposes a highly-efficient white emission organic EL element having a structure in which a plurality of light-emitting units are stacked. In the organic EL element, a monochromatic light-emitting unit and a polychromatic light-emitting unit are stacked with a charge-generating layer interposed between the monochromatic light-emitting unit and the polychromatic light-emitting unit. However, suppression of a color variation and a chromaticity change which are important for lighting applications is not considered, and it is difficult to say that the organic EL element can sufficiently deal with the chromaticity change.

Patent Literature 2 (JP-2011-70963 A) proposes an element structure which includes two kinds of green light-emitting materials and can decrease a chromaticity change also at various color temperatures such as white, warm white, and light bulb color. Although the element structure can achieve a long life, the structure causes a different life when the color temperature is changed, which causes a short life as a high color temperature is changed to a low color temperature (see columns of Examples). A technique for suppressing the chromaticity change at various color temperatures has been further desired.

The present invention was made in view of the problems described above, and it is an object of the present invention to provide an organic electroluminescence element and an illumination device which can suppress a chromaticity change which is important for lighting applications, and achieve a high efficiency, a long life, and a high color rendering property.

### Means of Solving the Problems

An organic electroluminescence element according to the present invention includes a positive electrode, a negative electrode, a first light-emitting unit including at least one light-emitting layer, a second light-emitting unit including two or more light-emitting layers, and an intermediate layer. The organic electroluminescence element has a multi-unit structure in which the first light-emitting unit and the second light-emitting unit are stacked with the intermediate layer interposed between the first light-emitting unit and the second light-emitting unit. The multi-unit structure is interposed between the positive electrode and the negative electrode. The organic electroluminescence element provides a white emission color. The at least one light-emitting layer of the first light-emitting unit includes a blue light-emitting material. The second light-emitting unit has a stacked structure of the two or more light-emitting layers in which a red light-emitting layer including a red light-emitting material and a green light-emitting layer including a green light-emitting material are stacked. One of the red light-emitting layer and the green light-emitting layer of the second light-emitting unit is closer to the positive electrode than the other of the red light-emitting layer and the green light-emitting layer of the second light-emitting unit, and includes a hole-transporting material as a host material. The other of the red light-emitting layer and the green light-emitting layer of the second light-emitting unit is closer to the negative electrode than the one of the red light-emitting layer and the green light-emitting layer of the second light-emitting unit, and includes an electron-transporting material as a host material.

As a preferable aspect of the organic electroluminescence element, the red light-emitting material and the green light-emitting material in the second light-emitting unit are phosphorescent light-emitting materials.

As a preferable aspect of the organic electroluminescence element, the first light-emitting unit includes a blue fluorescent light-emitting material and a green fluorescent light-emitting material.

As a preferable aspect of the organic electroluminescence element, a difference between peak wavelengths of the red light-emitting material and the green light-emitting material in the second light-emitting unit is 75 nm or less.

As a preferable aspect of the organic electroluminescence element, a peak wavelength of the red light-emitting material in the second light-emitting unit is 610 nm or more.

As a preferable aspect of the organic electroluminescence element, the at least one light-emitting layer of the first light-emitting unit includes a hole-transporting material as a host material on a side of the positive electrode and an electron-transporting material as a host material on a side of the negative electrode.

As a preferable aspect, the organic electroluminescence element includes the following configuration. The intermediate layer is a first intermediate layer. The organic electroluminescence element further includes a second intermediate layer; and a third light-emitting unit including two or more light-emitting layers. The third light-emitting unit is stacked on the first light-emitting unit or the second light-emitting unit with the second intermediate layer interposed between the third light-emitting unit and the first light-emitting unit or the second light-emitting unit. The third light-emitting unit has a stacked structure of the two or more light-emitting layers in which a red light-emitting layer including a red light-emitting material and a green light-emitting layer including a green light-emitting material are stacked. One of the red light-emitting layer and the green light-emitting layer of the third light-emitting unit is closer to the positive electrode than an other of the red light-emitting layer and the green light-emitting layer of the third light-emitting unit, and includes a hole-transporting material as a host material. The other of the red light-emitting layer and the green light-emitting layer of the third light-emitting unit is closer to the negative electrode than the one of the red light-emitting layer and the green light-emitting layer of the third light-emitting unit, and includes an electron-transporting material as a host material.

As a preferable aspect of the organic electroluminescence element, one of the positive electrode and the negative electrode is a reflective electrode; and the first light-emitting unit is disposed closest to the reflective electrode among a plurality of light-emitting units that include at least the first light-emitting unit and the second light-emitting unit.

An illumination device according to the present invention includes the organic electroluminescence element.

### Effect of the Invention

The present invention can provide an organic electroluminescence element and an illumination device which can suppress a chromaticity change and achieve a high efficiency, a long life, and a high color rendering property.

### BRIEF DESCRIPTION OF DRAWINGS

FIG. 1 is a schematic sectional view of an example of an organic electroluminescence element in an embodiment;

FIG. 2 is a schematic sectional view of an example of the organic electroluminescence element in the embodiment;

FIG. 3 is a schematic sectional view of an example of the organic electroluminescence element in the embodiment;

FIG. 4 is a schematic sectional view of an example of the organic electroluminescence element in the embodiment;

FIG. 5 is a schematic sectional view of an example of the organic electroluminescence element in the embodiment;

FIG. 6 is a schematic sectional view of an example of the organic electroluminescence element in the embodiment;

FIG. 7A is a u′v′ chromaticity diagram, and shows a color in a coordinate system;

FIG. 7B shows a MacAdam ellipse in a u′v′ chromaticity diagram;

FIG. 8A is a graph showing a relation between a peak wavelength difference and a chromaticity change of a light-emitting material, and is a graph of Δu′;

FIG. 8B is a graph showing a relation between a peak wavelength difference and a chromaticity change of a light-emitting material, and is a graph of Δv′; and

FIG. 8C is a graph showing a relation between a peak wavelength difference and a chromaticity change of a light-emitting material, and is a graph of Δu′/Δv′.

### DESCRIPTION OF EMBODIMENTS

An organic electroluminescence element (organic EL element) according to the present invention includes a positive electrode 1, a negative electrode 2, a first light-emitting unit 5a including at least one light-emitting layer 10, a second light-emitting unit 5b including two or more light-emitting layers 10, and an intermediate layer 3. The organic EL element has a multi-unit structure in which the first light-emitting unit 5a and the second light-emitting unit 5b are stacked with the intermediate layer 3 interposed between the first light-emitting unit 5a and the second light-emitting unit 5b. The multi-unit structure is interposed between the positive electrode 1 and the negative electrode 2. The organic EL element provides a white emission color. The at least one light-emitting layer 10 of the first light-emitting unit 5a includes a blue light-emitting material. The second light-emitting unit 5b have a stacked structure of the light-emitting layers 10 in which a red light-emitting layer 10R including a red light-emitting material and a green light-emitting layer 10G including a green light-emitting material are stacked. One of the red light-emitting layer 10R and the green light-emitting layer 10G of the second light-emitting unit 5b is closer to the positive electrode 1 than the other of the red light-emitting layer 10R and the green light-emitting layer 10G of the second light-emitting unit 5b, and includes a hole-transporting material as a host material. The other of the red light-emitting layer 10R and the green light-emitting layer 10G of the second light-emitting unit 5b is closer to the negative electrode 2 than the one of the red light-emitting layer 10R and the green light-emitting layer 10G of the second light-emitting unit 5b, and includes an electron-transporting material as a host material.

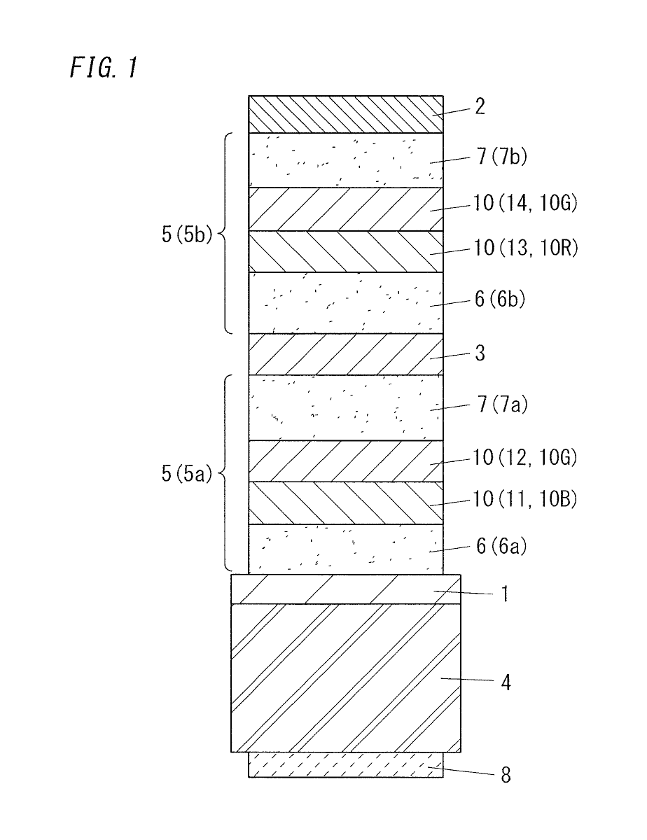

FIG. 1 shows an example of the organic EL element in the embodiment. The organic EL element has a multi-unit structure including a plurality of light-emitting units 5. The organic EL element has a multi-unit structure in which a first light-emitting unit 5a including at least one light-emitting layer 10 and a second light-emitting unit 5b including two or more light-emitting layers 10 are stacked with an intermediate layer 3 interposed between the first light-emitting unit 5a and the second light-emitting unit 5b. The multi-unit structure is interposed between a positive electrode 1 and a negative electrode 2. The organic EL element provides a white emission color. The organic EL element includes the plurality of light-emitting layers 10, which makes it possible to adjust an emission color to emit white light. For example, when including the light-emitting layers 10 emitting light of the primary colors green, red, and blue, the organic EL element can provide white emission. Hereinafter, the embodiment will be described using the form of FIG. 1 as a representative example, but this structure is merely an example, and the present invention is not limited to the structure within the intent of the present invention.

In the organic EL element of the form of FIG. 1, the positive electrode 1, the first light-emitting unit 5a, the intermediate layer 3, the second light-emitting unit 5b, and the negative electrode 2 are stacked in this order on a surface of a substrate 4. The plurality of light-emitting units 5 can provide an organic EL element which provides easy adjustment of white, can suppress a chromaticity change, and has a long life. Herein, the light-emitting unit 5 is a stacked structure functioning to emit light when a voltage is applied to the light-emitting unit 5 in a state where the light-emitting unit 5 is sandwiched between a pair of electrodes (the positive electrode 1 and the negative electrode 2). The multi-unit structure is a structure in which the plurality of light-emitting units 5 are stacked with the intermediate layer 3 interposed between two adjacent light-emitting units 5 of the plurality of light-emitting units 5. The intermediate layer 3 in the multi-unit structure has light transmitting property and a charge injection property to the upper and lower light-emitting units 5. Thereby, the element can be activated by injecting charges (electrons and holes) into the upper and lower light-emitting units 5, and can transmit light to emit the light to the outside. In the multi-unit structure, the plurality of light-emitting units 5 stacked in a thickness direction of the element are electrically connected in series between the pair of electrodes.

In the present form, the number of the light-emitting units 5 is two, and the light-emitting units 5 are the first light-emitting unit 5a and the second light-emitting unit 5b. The number of the light-emitting units 5 may be 4 or more. An increase in the number of the light-emitting units may cause a complicated element configuration and may cause difficult color adjustment, and accordingly the number of the light-emitting units 5 is preferably small, and may be 5 or less, for example. From the viewpoints of element design, ease of color adjustment, and a reduction in a thickness, the number of the light-emitting units 5 is preferably 4 or less, and more preferably 2 or 3.

In the organic EL element of the present form, the layers are stacked on the substrate 4. The substrate 4 is a supporting substrate on which the layers included in the organic EL element are stacked. By using the substrate 4, the layers can be stably formed, and the element having a good emission property can be obtained. When light is taken from a side of the substrate 4, the substrate 4 is preferably a transparent substrate having light transmitting property. As the substrate 4, for example, a glass substrate or the like can be used. When the substrate 4 is a glass substrate, glass has high moisture-proofness, which can suppress degradation of the element caused by moisture. A light-extraction property can be improved by using transparent glass. In the present form, the substrate 4 has light transmitting property, and light emitted by the light-emitting layer 10 is taken out to the outside through the substrate 4. Therefore, the organic EL element has a so-called bottom emission structure. Of course, the organic EL element may have a top emission structure in which light is taken out from the opposite side of the element from the substrate 4. The organic EL element may have a double-sided extraction structure in which light is taken out from both sides. In the present form, the positive electrode 1 is formed on a surface of the substrate 4. A layer configuration in which the positive electrode 1 is disposed on the side of the substrate 4 among the pair of electrodes is a so-called sequential layer configuration, and can facilitate formation of the element. Of course, the layer configuration may be a structure (reverse layer configuration) in which the negative electrode 2 is disposed on the side of the substrate 4. A light-extraction structure may be provided between the substrate 4 and the positive electrode 1. The light-extraction property can be improved by providing the light-extraction structure. The light-extraction structure may include a resin layer having a refractive index higher than a refractive index of glass, a resin layer including light-scattering particles, high refractive-index glass or the like.

In the present form, a light-extraction layer 8 is provided on a surface (facing an external side) opposite to the surface of the substrate 4 on which the light-emitting layer 10 is provided. By providing the light-extraction layer 8, reflective loss between the substrate 4 and the external can be suppressed, and a light-extraction efficiency can be improved. The light-extraction layer 8 may be a layer having a light scattering property. In that regard, lights emitted at various angles from the light-emitting layer 10 can be sufficiently mixed by the scattering property, to decrease a chromaticity shift according to an angle of a viewing direction. Particularly, in a panel-like organic EL element providing white emission, it is important to emit light without causing a color shift in a viewing direction in lighting applications or the like. Emission having no angle dependence can be obtained by providing the light-extraction layer 8. The light-extraction layer 8 can be formed by, for example, pasting a light-extraction film having a light scattering structure. Thereby, the light-extraction layer 8 can be easily provided. The light scattering structure may be provided by processing the surface of the substrate 4 in place of the light-extraction layer 8, or in addition to the light-extraction layer 8. Also in that regard, light is scattered, and thereby a light-extraction property can be improved. For example, the light scattering structure can be provided on the substrate 4 by subjecting the substrate 4 to surface roughening. The substrate 4 can be subjected to surface roughening by an appropriate method such as sandblast or reactant etching, for example.

The positive electrode 1 and the negative electrode 2 are paired with each other. When a voltage is applied, holes are injected from the positive electrode 1, and electrons are injected from the negative electrode 2. A light-extraction side electrode (positive electrode 1) preferably has light transmitting property. The positive electrode 1 can include a transparent conductive layer. An electrode (negative electrode 2) located on a side opposite to the light-extraction side may have light reflectivity. In such a case, light emitted from the light-emitting layer 10 toward the side of the negative electrode 2 can be reflected, and the reflected light can be taken out from the side of the substrate 4. The positive electrode 1 may be constituted as a layer. The negative electrode 2 may be constituted as a layer.

As described above, as a preferable aspect, one of the positive electrode 1 and the negative electrode 2 is a reflective electrode. The reflective electrode may be disposed as an electrode located on a side opposite to the light-extraction side. Since light can be reflected and taken out by providing the reflective electrode, a light-extraction efficiency can be improved. The reflective electrode is an electrode reflecting light. In this case, an electrode other than the reflective electrode among the positive electrode 1 and the negative electrode 2 may be a light-transmitting electrode. In the form of FIG. 1, the negative electrode 2 may be the reflective electrode, and the positive electrode 1 may be the light-transmitting electrode. Of course, when light is taken out from the side of the negative electrode 2, the negative electrode 2 may be the light-transmitting electrode, and the positive electrode 1 may be the reflective electrode.

The positive electrode 1 is an electrode injecting holes into the light-emitting layer 10. Electrode materials including a metal, an alloy, and an electrically conductive compound which have a large work function, or mixtures of these are preferably used as a material for the positive electrode 1. A material having a work function of 4 eV or more and 6 eV or less is preferably used as the material for the positive electrode 1 in order to prevent a difference with a HOMO (Highest Occupied Molecular Orbital) level from increasing too much. Examples of the electrode material for the positive electrode 1 include ITO, tin oxide, zinc oxide, IZO, copper iodide, a conductive polymer such as PEDOT or polyaniline, a conductive polymer doped with an optional acceptor or the like, and a conductive light-transmitting material such as a carbon nanotube. Herein, the positive electrode 1 can be formed as a thin film by a sputtering method, a vacuum evaporation method, and an applying method or the like when the positive electrode 1 is formed on the surface of the substrate 4. The refractive index of the transparent positive electrode 1 can be, for example, about 1.8 to 2, and is not limited thereto. In order to reduce total reflection loss on the interface between an organic layer and a transparent substrate, the difference between the refractive indexes of the positive electrode 1 and the substrate 4 is preferably smaller. The sheet resistance of the positive electrode 1 is preferably hundreds Ω/□ (Ω/square) or less, and particularly preferably 100Ω/□ or less. Herein, the film thickness of the positive electrode 1 may be to 500 nm or less, and preferably in a range of 10 nm to 200 nm. When light is taken out through the positive electrode 1, the transmissivity of the light is improved as the positive electrode 1 is thinner. However, since the sheet resistance increases in inverse proportion to the film thickness, applying of a high voltage may be required and nonuniformity of luminance uniformity (based on unevenness of a current density distribution caused by a voltage drop) may be generated when the area of the element increases. In order to avoid this trade-off, a grid-like auxiliary wiring including a metal or the like may be also effectively formed on the positive electrode 1. In this case, in order to prevent the grid wiring from working as a shading material, a grid part is more preferably subjected to insulating processing to prevent a current from flowing toward the light-emitting layer 10.

The negative electrode 2 is an electrode injecting electrons into the light-emitting layer 10. Electrode materials including a metal, an alloy, and an electrically conductive compound which have a small work function, or mixtures of these are preferably used as a material for the negative electrode 2. A material having a work function of 1.9 eV or more and 5 eV or less is preferably used as the material for the negative electrode 2 in order to prevent a difference with a LUMO (Lowest Unoccupied Molecular Orbital) level from increasing too much. Examples of the electrode material for the negative electrode 2 include aluminum, silver, magnesium, and alloys of the metals with other metals (such as a magnesium-silver mixture, a magnesium-indium mixture, and an aluminum-lithium alloy). There can be used a metal conductive material, a metal oxide, and mixtures of these with other metals (such as a stacked film including an ultrathin film (herein, a thin film which can pass electrons during tunnel injection and has a thickness of 1 nm or less) made of aluminum oxide, and a thin film made of aluminum).

The intermediate layer 3 is provided between the adjacent light-emitting units 5 and 5. The intermediate layer 3 is made of a metal compound, a conductive material such as a mixture of the metal compound with an organic matter, and/or an insulating material such as a stacked structure of an electron-drawing material and an organic matter. The intermediate layer 3 injects electrons and holes into the upper and lower light-emitting units 5. Thus, the plurality of light-emitting units 5 are electrically connected in series with the intermediate layer 3 interposed between the two adjacent light-emitting units 5 of the plurality of light-emitting units 5. That is, the first light-emitting unit 5a, the intermediate layer 3, and the second light-emitting unit 5b are disposed, not in parallel but in series, between the pair of electrodes. Such an element structure is called a two-stage multi-unit. Thereby, electrons and holes flow evenly in the light-emitting layers 10, which provides well-balanced emission, a high efficiency, and a long life. The two-stage multi-unit configuration facilitates layer stacking, which can provide an improvement in productivity.

The intermediate layer 3 may be a single layer or may include a plurality of layers. In case of the single layer, the element configuration is simpler, and its production is easier. The multiple layer configuration allows use of layer materials which are appropriate for electron transport and hole transport to the respective light-emitting units 5, and can achieve a further improvement in an efficiency, and a longer life.

In the present form, in a state where the intermediate layer 3 is sandwiched, the first light-emitting unit 5a is disposed on the side of the positive electrode 1 and the second light-emitting unit 5b is disposed on the side of the negative electrode 2. However, disposition of the light-emitting units 5 is not limited thereto. For example, the first light-emitting unit 5a may be disposed on the side of the negative electrode 2, and the second light-emitting unit 5b may be disposed on the side of the positive electrode 1. When the organic EL element includes three or more light-emitting units 5, the first light-emitting unit 5a and the second light-emitting unit 5b may be disposed at any of positions of the plurality of light-emitting units 5.

The light-emitting unit 5 includes at least one light-emitting layer 10. The light-emitting unit 5 including the light-emitting layer 10 can emit light. In the present form, each light-emitting unit 5 includes two light-emitting layers 10. That is, the first light-emitting unit 5a includes a first light-emitting layer 11 and a second light-emitting layer 12. The second light-emitting unit 5b includes a third light-emitting layer 13 and a fourth light-emitting layer 14. Therefore, as the plurality of light-emitting layers 10, the first light-emitting layer 11, the second light-emitting layer 12, the third light-emitting layer 13, and the fourth light-emitting layer 14 are disposed in this order from the side of the positive electrode 1 toward the side of the negative electrode 2. The number of the light-emitting layers 10 in the light-emitting unit 5 is not limited thereto. The first light-emitting unit 5a may include one or more light-emitting layers 10, and may be a unit including one light-emitting layer 10. The number of the light-emitting layers 10 may be 3 or more in any of the first light-emitting unit 5a and the second light-emitting unit 5b or in both of the first light-emitting unit 5a and the second light-emitting unit 5b. The number of the light-emitting layers 10 in one light-emitting unit 5 is preferably 5 or less, more preferably 3 or less, and still more preferably 2 because an increase in the number of the light-emitting layers 10 may complicate color adjustment instead.

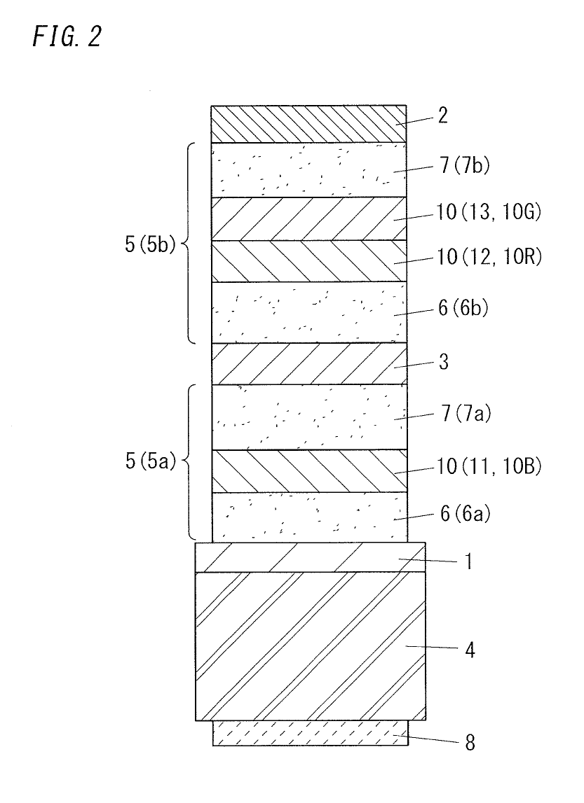

FIG. 2 shows a modified example of the form of FIG. 1, and shows a layer configuration when the number of light-emitting layers 10 of a first light-emitting unit 5a is one. In FIG. 2, the same reference numerals are used to denote the same configurations as those in FIG. 1. The light-emitting layers 10 are numbered from a side of a substrate 4. In the form of FIG. 2, the first light-emitting unit 5a includes a first light-emitting layer 11. A second light-emitting unit 5b includes a second light-emitting layer 12 and a third light-emitting layer 13. It is easily understood that the second light-emitting layer 12 in the form of FIG. 2 corresponds to the third light-emitting layer 13 in the form of FIG. 1 and that the third light-emitting layer 13 in the form of FIG. 2 corresponds to the fourth light-emitting layer 14 in the form of FIG. 1. Hereinafter, the form of FIG. 1 will be mainly described, and the described configuration can be applied also to the form of FIG. 2.

The light-emitting layer 10 is a layer recombining holes (positive holes) injected from a positive electrode 1 and electrons injected from a negative electrode 2, to emit light. The light-emitting layer 10 may has a configuration in which a dopant (light-emitting material) as a light-emitting material is doped into a layer medium included in the light-emitting layer 10. The layer medium can be made of a material which can transport charges, or the like. The layer medium is a so-called host. In the present disclosure, one layer included in the light-emitting layer 10 is defined as a layer including the same dopant. Therefore, as long as the dopant is the same even if a host material is changed in the middle of a thickness of the light-emitting layer 10, it is considered that the number of the light emitting layer 10 including the dopant is one.

It is preferable that a plurality of light-emitting layers 10 are adjacently stacked in a light-emitting unit 5. Thereby, light can be efficiently emitted. In the form of FIG. 1, the first light-emitting layer 11 and the second light-emitting layer 12 are adjacently formed. The third light-emitting layer 13 and the fourth light-emitting layer 14 are adjacently formed.

The light-emitting unit 5 preferably includes layers (charge transfer layers) injecting and transporting electrons and holes. Thereby, charges can be smoothly transferred from an electrode or an intermediate layer 3 to the light-emitting layer 10, and a long life can be achieved while an emission efficiency is improved. Examples of the charge transfer layers include a hole injection layer, a hole transport layer 6, an electron transport layer 7, and an electron injection layer.

In the organic EL element in the form of FIG. 1, each light-emitting unit 5 includes the hole transport layer 6 on the positive electrode 1 side of the light-emitting layer 10, and the electron transport layer 7 on the negative electrode 2 side of the light-emitting layer 10. That is, the first light-emitting unit 5a includes a first hole transport layer 6a on the positive electrode 1 side of the first light-emitting layer 11, and a first electron transport layer 7a on the negative electrode 2 side (intermediate layer 3 side) of the second light-emitting layer 12. The second light-emitting unit 5b includes a second hole transport layer 6b on the positive electrode 1 side (intermediate layer 3 side) of the third light-emitting layer 13 and a second electron transport layer 7b on the negative electrode 2 side of the fourth light-emitting layer 14. By providing the hole transport layer 6 and the electron transport layer 7, holes and electrons are smoothly transferred, which can provide an improvement in an emission efficiency. The hole injection layer may be provided between the positive electrode 1 and the hole transport layer 6 (first hole transport layer 6a) and/or between the intermediate layer 3 and the hole transport layer 6 (second hole transport layer 6b). Thereby, a hole injection property can be improved. The electron injection layer may be provided between the negative electrode 2 and the electron transport layer 7 (second electron transport layer 7b) and/or between the intermediate layer 3 and the electron transport layer 7 (first electron transport layer 7a). Thereby, an electron injection property can be improved. Thus, in the organic EL element, by appropriately providing a functional layer promoting transfer of the charges, a high efficiency and a long life can be achieved.

In the organic EL element of the present form, at least one light-emitting layer 10 of the first light-emitting unit 5a includes a blue light-emitting material. In this form, the first light-emitting unit 5a includes a blue light-emitting layer 10B. The light-emitting layers 10 of the second light-emitting unit 5b have a stacked structure in which a red light-emitting layer 10R including a red light-emitting material and a green light-emitting layer 10G including a green light-emitting material are stacked. The organic EL element which includes blue, red, and green light-emitting materials can further facilitate white emission.

In the form of FIG. 1, among the two light-emitting layers 10 in the first light-emitting unit 5a, the first light-emitting layer 11 is the blue light-emitting layer 10B including the blue light-emitting material. The second light-emitting layer 12 is the green light-emitting layer 10G including the green light-emitting material. The disposition (color order, stacking order) of the blue light-emitting layer 10B and the green light-emitting layer 10G in the first light-emitting unit 5a is not limited thereto, and the second light-emitting layer 12 may be the blue light-emitting layer 10B. In this case, the first light-emitting layer 11 may be the green light-emitting layer 10G.

In the second light-emitting unit 5b, among the two light-emitting layers 10, the third light-emitting layer 13 is the red light-emitting layer 10R, and the fourth light-emitting layer 14 is the green light-emitting layer 10G. The color order (stacking order) of the light-emitting layers 10 in the second light-emitting unit 5b is not limited thereto. The third light-emitting layer 13 may be the green light-emitting layer 10G, and the fourth light-emitting layer 14 may be the red light-emitting layer 10R.

In the plurality of light-emitting layers 10 included in the organic EL element, a plurality of (two in the present form) green light-emitting layers 10G are included as a preferable aspect. Green has a large effect on visual sense. When green intensity is high, emission is strongly felt as compared with the case where intensity of the other colors is high. When the green intensity is strong, a color change is less likely to be felt. Therefore, by providing the plurality of green light-emitting layers 10G, color adjustment can be easily performed, and a chromaticity change can be suppressed, which can provide an element having a high emission performance.

In the present form, in the second light-emitting unit 5b, one of the red light-emitting layer 10R and the green light-emitting layers 10G is closer to the positive electrode 1 than the other of the red light-emitting layer 10R and the green light-emitting layer 10G, and includes a hole-transporting material as a host material. In the second light-emitting unit 5b, the other of the red light-emitting layer 10R and the green light-emitting layer 10G is closer to the negative electrode 2 than the one of the red light-emitting layer 10R and the green light-emitting layer 10G, and includes an electron-transporting material as a host material. That is, the third light-emitting layer 13 disposed closer to the positive electrode 1 is a layer in which a light-emitting material is doped into a hole-transporting material. The fourth light-emitting layer 14 disposed closer to the negative electrode 2 is a layer in which a light-emitting material is doped into an electron-transporting material. Specifically, the third light-emitting layer 13 is a layer into which a red light-emitting material is doped. The fourth light-emitting layer 14 is a layer into which a green light-emitting material is doped. Thus, in the stacked light-emitting layers 10, the host material in the light-emitting layer being closer to the positive electrode 1 is made different from the host material in the light-emitting layer being closer to the negative electrode 2, and thereby a chromaticity change can be suppressed, and a high efficiency, a long life, and a high color rendering property can be achieved. That is, when the stacked light-emitting layers 10 are made of a single host material, or the light-emitting layers 10 are stacked without optimizing the host material, the chromaticity change tends to increase, and the emission performance may decrease. However, in the present form, the light-emitting layer 10 being closer to the positive electrode 1 in the stacked structure of the plurality of light-emitting layers 10 includes the hole-transporting material, and the light-emitting layer 10 being closer to the negative electrode 2 includes the electron-transporting material. Therefore, the transfer of the charges can be optimized, and the chromaticity change can be suppressed.

The hole-transporting material is a material having hole mobility higher than electron mobility, for charge mobilities of holes (positive holes) and electrons. The electron-transporting material is a material having electron mobility higher than hole mobility, for charge mobilities of holes (positive holes) and electrons. For the difference between charge transport properties in the hole transport layer and the electron transport layer, one of the hole and the electron is preferably equal to or more than 10 times of the other of the hole and the electron, more preferably equal to or more than 100 times, still more preferably equal to or more than 1000 times, and yet still more preferably equal to or more than 10000 times. The transport properties of the hole and the electron can be expressed by charge mobility. The charge mobility can be confirmed by measuring the mobilities of the hole and the electron by using a technique such as a TOF method, impedance spectrum, transient EL measurement, or a dark injection method. Examples of the host material include a material having a transport property for both the hole and the electron (both charge-transporting material in which the transport property of the hole is close to the transport property of the electron) such as a so-called bipolar material. However, in the present form, the chromaticity change can be suppressed by optimizing the host material for the light-emitting layer 10 as described above.

Herein, the chromaticity change includes a variation in an emission color for every manufactured organic EL element. That is, even if layers made of the same material are stacked by the same method in the organic EL element, slightly different emission colors may be generated by the difference between delicate conditions (environments) during manufacturing, or the like. Particularly, it is important that a variation in chromaticity is prevented because the difference in colors is likely to be visually confirmed in the organic EL element providing white emission. A plurality of organic EL elements may be arranged in a planar form to provide panel-like organic EL elements as a planar illumination body. In that regard, when the emission colors of the organic EL elements are slightly different, emission having a different color is noticeable, which may cause a deterioration in an illumination property. However, in the organic EL elements of the present form, it is possible to suppress a change (difference) in the chromaticity of the emission color for every organic EL element, and to suppress the difference between hues of the emission colors to a visually unrecognizable degree. Therefore, the organic EL elements having the suppressed chromaticity change can be obtained. The chromaticity change may be represented by a color difference.

The chromaticity change includes the chromaticity change of the organic EL element with time. In the organic EL element, a ratio of intensity of every light-emitting material is changed with time during use, which may cause a change in the chromaticity of the emission color. Particularly, it is important that a change in chromaticity with time is suppressed because a change in a color is likely to be visually confirmed in the organic EL element providing white emission. When the plurality of panel-like organic EL elements may be arranged in a planar form to provide the planar illumination body as described above, and the degree of the chromaticity change of the emission color is different for every organic EL element, emission having a different color is noticeable, which may cause a deterioration in an illumination property. However, even when the organic EL element of the present form is used, a color balance is less likely to be lost, which can suppress the change (change with time) in the chromaticity of the emission color of the organic EL element, and suppress the difference between hues of the emission colors to a visually unrecognizable degree. Therefore, the organic EL element having the suppressed chromaticity change can be obtained.

The emission spectrum of the organic EL element in the visible region (wavelength: about 400 to 800 nm) is observed using an optical instrument such as a spectroradiometer. The emission spectrum shows the emission intensity, on a relative basis, for each wavelength. There can be used a blue emission dopant having an emission peak in a blue wavelength region, a green emission dopant having an emission peak in a green wavelength region, and a red emission dopant having an emission peak in a red wavelength region within the visible light region. There can be used a blue emission dopant having maximum emission intensity (emission peak) in a blue wavelength region (for example, wavelength: about 450 to 490 nm). There can be used a green emission dopant having maximum emission intensity (emission peak) in a green wavelength region (for example, wavelength: about 500 to 570 nm). There can be used a red emission dopant having maximum emission intensity (emission peak) in a red wavelength region (for example, wavelength: about 590 to 650 nm). Various emission colors are obtained, and in particular white emission is obtained, by combining the primary colors red, green, and blue.

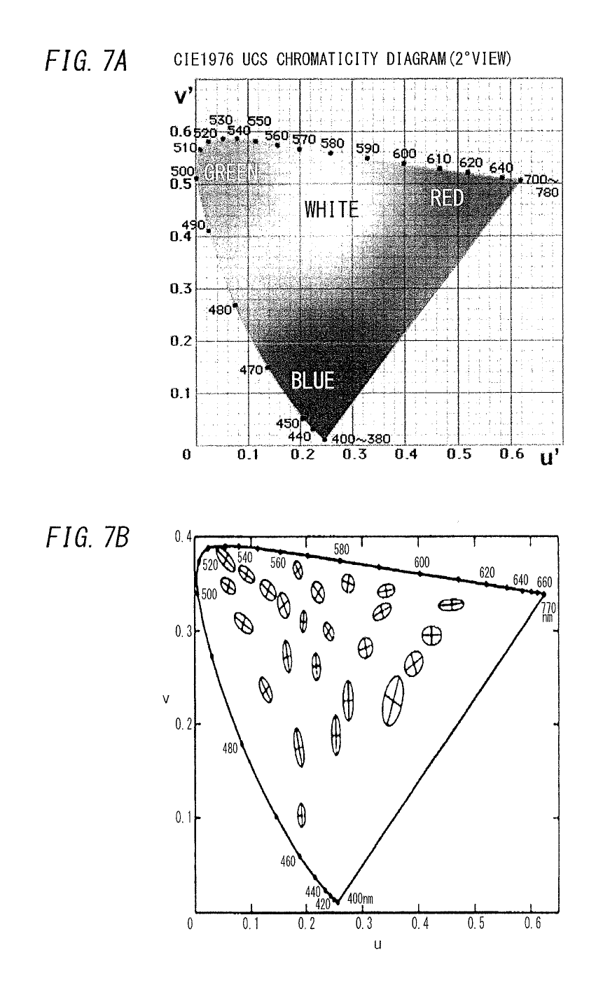

FIGS. 7A and 7B are collectively referred to as FIG. 7. FIG. 7 shows a u′v′ chromaticity diagram [CIE 1976 UCS chromaticity diagram (2° view)]. FIG. 7A shows a color in a coordinate system. FIG. 7B shows a MacAdam ellipse. A uv coordinate is correctly shown in the coordinate system of FIG. 7B. The relation of v′=1.5×v is set in the uv coordinate. The MacAdam ellipse of FIG. 7B is enlarged by 10 times. The chromaticity diagram is drawn in gray in FIG. 7A. However, a person skilled in the art knows that the chromaticity diagram is drawn in colors, and provides a distribution of colors which is illustrated.

The principle of an emission color of a multi-unit structure will be described with reference to the chromaticity diagram of FIG. 7A. White emission can be produced by mixing colors. In the chromaticity diagram of FIG. 7A, a monochromatic light-emitting material is shown at a position near an outer edge (on a curve in which a wavelength is described) of a figure shown in the chromaticity diagram. For example, when a blue light-emitting layer 10B having a wavelength of 450 nm and a green light-emitting layer 10G having a wavelength of 540 nm are stacked in one light-emitting unit 5, a color produced by mixing is disposed on a straight line (on a line segment) connecting a point of 450 nm and a point of 540 nm on the outer edge of the chromaticity diagram of FIG. 7A. The light-emitting unit 5 may be the first light-emitting unit 5a. In this case, a position where the color produced by mixing is disposed on the straight line is determined by an intensity ratio of the colors, or the like. For example, when the intensities of the colors are equal to each other, the color produced by mixing is at a position corresponding to half of the straight line. Thus, the coordinate of the color produced by the first light-emitting unit 5a is referred to as a first color coordinate. When a green light-emitting layer 10G having a wavelength of 550 nm and a red light-emitting layer 10R having a wavelength of 620 nm are stacked in the other light-emitting unit 5, the color produced by mixing is disposed on a straight line (on a line segment) connecting a point of 550 nm and a point of 620 nm in the chromaticity diagram of FIG. 7A. This light-emitting unit 5 may be the second light-emitting unit 5b. In this case, a position where the color produced by mixing is disposed on the straight line is determined by an intensity ratio of the colors, or the like. For example, when the intensities of the colors are equal to each other, the color produced by mixing is at a position corresponding to the middle of the straight line. Thus, the coordinate of the color produced by the second light-emitting unit 5b is referred to as a second color coordinate. By mixing the colors produced by the two light-emitting units 5, a color coordinate of the emission color of the whole element is disposed on the straight line connecting the first color coordinate and the second color coordinate. When the color coordinate enters a white region located at the center of the chromaticity diagram, white light can be emitted.

As shown in FIG. 7B, in the chromaticity diagram, the range of the difference between colors which can be recognized is generally determined by using the MacAdam ellipse. Since the color coordinates of colors which are within the range of the MacAdam ellipse are close to each other, the colors may be determined to be the same by viewing (or no difference between colors). Therefore, an element having no chromaticity change can be constituted by making a color change fall within the range of the MacAdam ellipse even when the color change is generated. Herein, as shown in FIG. 7B, in the u′v′ chromaticity diagram, the MacAdam ellipse of the white region is disposed in a state where a short axis of the ellipse is in a direction along a u′ axis, and a long axis of the ellipse is in a direction along a v′ axis. Therefore, in order that the color change falls within the range of the ellipse even when the color change is generated, it is important to decrease a change in u′ having a short length in order to decrease the color difference with the changed color. As described above, the organic EL element providing white emission usually includes the blue light-emitting layer 10B, the red light-emitting layer 10R, and the green light-emitting layer 10G in order to produce white. In this case, delicate color adjustment (adjustment of a color temperature, or the like) for white is performed by setting the film thicknesses of the light-emitting layers 10, dopant concentrations and/or the like. In the form of FIG. 1, the first light-emitting unit 5a includes at least the blue light-emitting material, and the second light-emitting unit 5b includes the red light-emitting material and the green light-emitting material. In the organic EL element having such a multi-unit structure, changes in green emission intensity and red emission intensity strongly affect the chromaticity change of u′. It is important to suppress the changes as much as possible in order to decrease fluctuation in the color difference.

In the present form, a stacked structure of a hole-transporting host material and an electron-transporting host material is used for the stacked structure of the red light-emitting layer 10R and the green light-emitting layer 10G which strongly affects the changes in the color difference. Therefore, a chromaticity change of the element can be suppressed even when the film thickness of the light-emitting layer is made to be changed in order to achieve various color temperatures, and a stable chromaticity change can be achieved by decreasing the variation in the color upon a deterioration behavior. There can be constituted an organic EL element having a high efficiency, a long life, and a high color rendering property.

Herein, though grouped under a single term, white emission includes, in detail, various emission colors. In particular, in the field of illumination such as a fluorescent lamp or an electric lamp, color differences in white emission are important. It is important to prescribe the emission color of an organic EL element which is to replace a fluorescent lamp, or which is to exhibit the hue of a fluorescent lamp.

Hereinafter, specific emission colors (hues) for white emission are given. Emission of an appropriate color of the following emission colors can be obtained in the organic EL element of the present form.

Display: denomination: JIS standard (color temperature): color explanation

D: daylight color: 5700 to 7100 K: color of sunlight at noon on a clear day

N: day white: 4600 to 5400 K: color of sunlight in a time band which spans noon on a clear day

W: white: 3900 to 4500 K: color of sunlight two hours after sunrise

WW: warm white: 3200 to 3700K: color of evening sunlight

L: light bulb color: 2600 to 3150 K: color of a white light bulb

The above JIS standard is “JIS Z 9112, Classification of fluorescent lamps by light-source color and color rendering property”. The unit “K” of color temperature is “Kelvin”.

The organic EL element of the present form has the above-described configuration. The organic EL element can achieve a good emission balance of red (R), green (C), and blue (B), and suppress a chromaticity change in an emission color, which can stably provide excellent white emission conforming to JIS standard.

In the organic EL element, an appropriate color can be selected from among kinds of white colors. For example, the emission color may be an L color (light bulb color) having a color temperature of about 3000 K, a W color (white) having a color temperature of about 4000 K, and an N color (day white) having a color temperature of about 5000 K, or the like. In this case, the emission life can be prolonged, and there can be obtained a long-life organic EL element. As described above, white emission includes various emission colors, but conventional organic EL elements could not sufficiently suppress a small chromaticity change. It was thus difficult to maintain the hue of a white emission color, owing to the chromaticity change. However, in the organic EL element of the present form, a chromaticity change is small in various whites. The hue of white emission can be maintained, and the life can be prolonged.

In the present form, the second light-emitting unit 5b has the stacked structure of the light-emitting layers 10 which include the red light-emitting layer 10R including the red light-emitting material and the green light-emitting layer 10G including the green light-emitting material. In the form of FIG. 1, the red light-emitting layer 10R is the third light-emitting layer 13 disposed on the positive electrode 1 side, and the green light-emitting layer 10G is the fourth light-emitting layer 14 disposed on the negative electrode 2 side. The stacking order of the red light-emitting layer 10R and the green light-emitting layer 10G is not limited thereto. The red light-emitting layer 10R may be disposed on the negative electrode 2 side to constitute the fourth light-emitting layer 14, and the green light-emitting layer 10G may be disposed on the positive electrode 1 side to constitute the third light-emitting layer 13. The second light-emitting unit 5b may further include the blue light-emitting layer 10B.

In the present form, the red light-emitting material and the green light-emitting material in the second light-emitting unit 5b are phosphorescent light-emitting materials as a preferable aspect. In this case, in the form of FIG. 1, both the red light-emitting layer 10R which is the third light-emitting layer 13, and the green light-emitting layer 10G which is the fourth light-emitting layer 14 are phosphorescent light-emitting layers. The second light-emitting unit 5b is a phosphorescent unit, and the phosphorescent unit has a stacked structure of the light-emitting layers 10 which include the layer including the hole-transporting material and the layer including the electron-transporting material. Phosphorescent emission has a comparatively large color change, and accordingly the phosphorescent light-emitting layer having a large color change is incorporated to a stacked structure of a hole-transporting host and an electron-transporting host, which makes it possible to particularly effectively suppress the chromaticity change. The chromaticity change can be suppressed, and the high efficiency and the long life can be further achieved by using the red phosphorescent light-emitting material and the green phosphorescent light-emitting material which are easily obtained as a material for providing a high efficiency and a long life as compared with a fluorescent material.

In the present form, the first light-emitting unit 5a has the stacked structure of the light-emitting layers 10 which include the blue light-emitting layer 10B including the blue light-emitting material and the green light-emitting layer 10G including the green light-emitting material. In the form of FIG. 1, the blue light-emitting layer 10B is the first light-emitting layer 11 disposed on the positive electrode 1 side, and the green light-emitting layer 10G is the second light-emitting layer 12 disposed on the negative electrode 2 side. The stacking order of the blue light-emitting layer 10B and the green light-emitting layer 10G is not limited thereto. The blue light-emitting layer 10B may be disposed on the negative electrode 2 side to constitute the second light-emitting layer 12, and the green light-emitting layer 10G may be disposed on the positive electrode 1 side to constitute the first light-emitting layer 11. The first light-emitting unit 5a may further include the red light-emitting layer 10R.

The first light-emitting unit 5a includes a blue fluorescent light-emitting material and a green fluorescent light-emitting material as a preferable aspect. As in the form of FIG. 1, in the case of a stacked structure of the light-emitting layers 10 including the blue light-emitting layer 10B and the green light-emitting layer 10G, the dopant of the blue light-emitting layer 10B may be the blue fluorescent light-emitting material, and the dopant of the green light-emitting layer 10G may be the green fluorescent light-emitting material. When the light-emitting layer 10 in the first light-emitting unit 5a is a single layer, the blue fluorescent light-emitting material and the green fluorescent light-emitting material may be doped into the light-emitting layer 10 which is the single layer. In the case where the light-emitting material included in the first light-emitting unit 5a is a fluorescent light-emitting material, the first light-emitting unit 5a is a fluorescent unit. By using the fluorescent unit, an element having a suppressed chromaticity change and a long life can be obtained. A multi-unit structure including the phosphorescent unit and the fluorescent unit can further suppress the chromaticity change based on a mutual emission function between phosphorescence and fluorescence, and an organic EL element having a high efficiency and a long life can be obtained.

The blue fluorescent light-emitting material has a longer life than that of a blue phosphorescent light-emitting material. Emission from the first light-emitting unit 5a can be easily adjusted to the target color by using the green fluorescent light-emitting material for the first light-emitting unit 5a including such a blue fluorescent light-emitting material. Therefore, the emission color of the organic EL element is easily adjusted to white. For example, in order to achieve white having a low color temperature (for example, 3000 K), blue emission intensity included in the first light-emitting unit 5a is considered to be decreased as compared with the case where white having a high color temperature (for example, 5000 K) is achieved. In that regard, specifically, there may be used a technique for purposely employing the layer configuration or the layer structure for decreasing the emission efficiency of the first light-emitting unit 5a, to achieve the target white. In this case, the blue fluorescent light-emitting material and the green fluorescent light-emitting material are used for the first light-emitting unit 5a. Thereby, when the white having the low color temperature is achieved, white emission having the target low color temperature can be achieved without decreasing the emission efficiency during white emission by suppressing the intensity of blue phosphorescent emission to increase the intensity of green phosphorescent emission. The first light-emitting unit 5a includes a multicolor light-emitting layer including the blue fluorescent light-emitting material and the green fluorescent light-emitting material. Thereby, a broader emission spectrum can be achieved, and a high color rendering index (Ra) required in lighting applications can be achieved.

In the organic EL element including the phosphorescent unit and the fluorescent unit, the phosphorescent unit may be disposed on the negative electrode 2 side, and the fluorescent unit may be disposed on the positive electrode 1 side, but may be reversed. As shown in FIG. 1, it is more preferable that the fluorescent unit is disposed on the positive electrode 1 side, and the phosphorescent unit is disposed on the negative electrode 2 side. In this case, a high efficiency for white color can be achieved by disposing the phosphorescent unit having a high internal quantum efficiency on the negative electrode 2 side with few optical interference loss. In the case where the phosphorescent unit is disposed on the positive electrode 1 side and the fluorescent unit is disposed on the negative electrode 2 side, the life may be prolonged. However, since the emission efficiency may be decreased in this case, the above-mentioned disposition is more preferable.

The host material used for the light-emitting layer 10 (first light-emitting layer 11, second light-emitting layer 12) in the first light-emitting unit 5a is not in particularly limited, and an appropriate host material may be used. The host material for the first light-emitting layer 11 may be the same as, or different from the host material for the second light-emitting layer 12. In the case where the same host material is used, the first light-emitting layer 11 and the second light-emitting layer 12 can be more easily stacked. As the host material, there may be used the hole-transporting material, the electron-transporting material, or a material having both a hole transport property and an electron transport property (bipolar material). Similarly to the second light-emitting unit 5b, the hole-transporting material may be used as the host material for the first light-emitting layer 11 located on the positive electrode 1 side, and the electron-transporting material may be used as the host material for the second light-emitting layer 12 located on the negative electrode 2 side. Thereby, the stacked structure of the light-emitting layers 10 is further optimized, and the chromaticity change can be further suppressed. In this case, it can be said that the first light-emitting unit 5a includes the light-emitting layers 10 which include the hole-transporting material as the host material on the positive electrode 1 side, and include the electron-transporting material as the host material on the negative electrode 2 side.

The second light-emitting unit 5b includes the red light-emitting material and the green light-emitting material as described above. A difference between peak wavelengths of the red light-emitting material and the green light-emitting material in the second light-emitting unit 5b is preferably 75 nm or less. Thereby, in the organic EL element providing white emission, an amount of change of u′v′ when a ratio of the red emission intensity to the green emission intensity is changed can be decreased, and the chromaticity change can further be suppressed. The difference between emission peak wavelengths is more preferably 65 nm or less in order to suppress the chromaticity change. However, when the difference between the emission peak wavelengths is decreased, the color of the red light-emitting material is closer to the color of the green light-emitting material, which makes it difficult to obtain a function of producing a color from red and green. This may not easily provide white emission. Therefore, the difference between the emission peak wavelengths is preferably, for example, 20 nm or more, more preferably 40 nm or more, and still more preferably 50 nm or more.

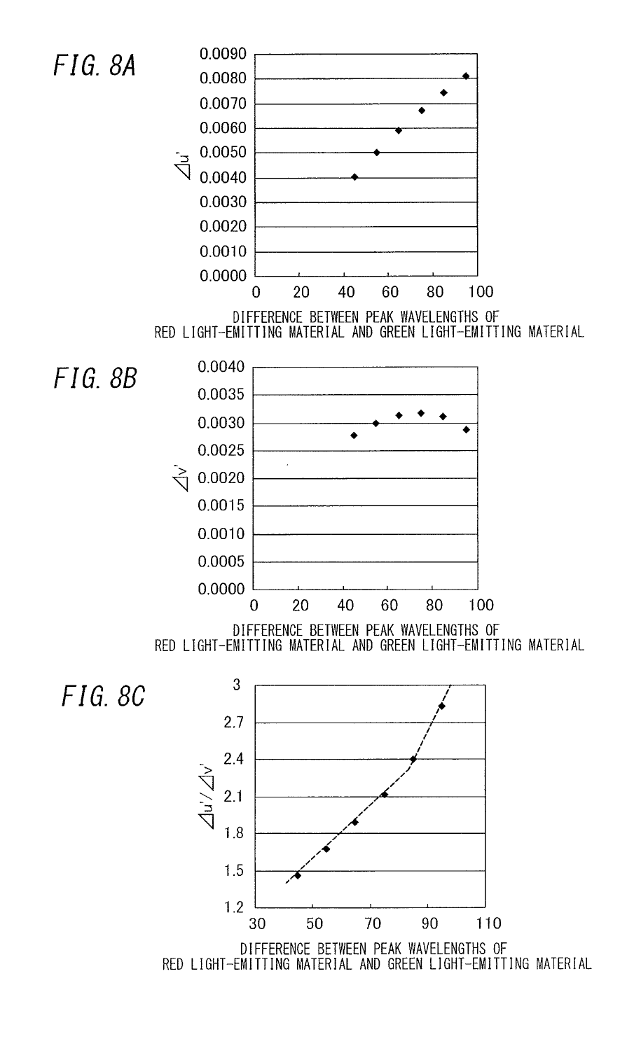

FIGS. 8A to 8C are collectively referred to as FIG. 8. FIG. 8 shows examples of the relation between peak wavelength differences and chromaticity changes of light-emitting materials. FIG. 8A is a graph of Δu′; FIG. 8B is a graph of Δv′, and FIG. 8C is a graph of Δu′/Δv′. The graph shows amounts of changes of chromaticities u′ and v′ when a red emission efficiency is improved by 10% and a green emission efficiency is reduced by 10% in the second light-emitting unit 5b in the organic EL element providing white emission as in the form of FIG. 1. FIG. 8A shows that Δu′ (initial u′-u′ after red and green emission intensities are changed) is increased when the difference between a red peak wavelength and a green peak wavelength is increased. FIG. 8B shows that Δv′ (initial v′-v′ after red and green emission intensities are changed) has the maximum point at about 75 nm. As shown in FIG. 8C, from these relations, it is found that when the difference between the peak wavelengths is more than 75 nm, a ratio of the amounts of change of u′ and v′ is changed, and the inclination of the graph is increased, which provides an increase in a ratio of the change of u′ to the change of v′. Therefore, in order to decrease the chromaticity change, it is particularly effective to decrease the change of u′. The difference between the peak wavelengths is preferably 75 nm or less, which is a range in which the ratio of the amounts of change of u′ to v′ can be further decreased.

The peak wavelength of the red light-emitting material in the second light-emitting unit 5b is preferably 610 nm or more. Thereby, white emission having a high special color rendering index R9 which is important for lighting applications can be achieved. Even when the red light-emitting material for the second light-emitting unit 5b has a peak wavelength of less than 610 nm, the red light-emitting material can provide red emission, and the whole organic EL element can provide white emission. However, in this case, the special color rendering index R9 tends to be decreased, and the illumination property may be decreased. Therefore, the color rendering property can be improved by setting the peak wavelength of the red light-emitting material to 610 nm or more to emit red light having darker redness.

Herein, the peak wavelength may be a wavelength having the maximum point (usually, the maximum intensity in the visible region) in the emission spectrum (graph showing the relation between a wavelength and intensity) of the light-emitting material.

The color rendering index is obtained by representing a color shift as an index. The color shift is produced when a light source illuminates a color chart for color rendering evaluation. The light source serves as a measuring object as compared with standard light defined by JIS (Japanese Industrial Standards). Examples of the color rendering index include an average color rendering index (Ra) and special color rendering indexes (R9 to R15). The average color rendering index (Ra) is obtained by averaging the color rendering indexes of eight colors (R1 to R8). The special color rendering indexes are specified as seven kinds: red (R9); yellow (R10); green (R11); blue (R12); a European's skin color (R13); a leaf color (R14); and a Japanese skin color (R15). The organic EL element of the present form can provide a high color rendering property in the average color rendering index (Ra) and the red special color rendering indexes (R9) which are important as white illumination, and can provide emission having a high illumination performance.

The organic EL element of FIG. 1 includes the red light-emitting layer 10R providing phosphorescent emission, the green light-emitting layer 10G providing phosphorescent emission, the blue light-emitting layer 10B providing fluorescent emission, and the green light-emitting layer 10G providing fluorescent emission. Accordingly, the emission color is formed by phosphorescent light of red and green, and fluorescent light of blue and green. Thus, emission is provided using phosphorescent light and fluorescent light. In particular, green emission is generated as a result of two kinds of emission, i.e. phosphorescence and fluorescence, and thereby emission chromaticity and luminance are adjusted, which achieves a good emission balance. The conversion efficiency from electric energy to light can be improved, and changes in luminance and chromaticity can be suppressed, even after prolonged emission. That is, the luminance life of green emission is extended by stacking two green light-emitting layers 10G of phosphorescent green and fluorescent green. As a result, the chromaticity changes can be reduced and the life can be prolonged. Since the host material in the light-emitting layers 10 providing phosphorescent emission includes the electron-transporting material and the hole-transporting material in the present form, the chromaticity change can be further suppressed.

In the case where both the first light-emitting unit 5a and the second light-emitting unit 5b include the green light-emitting material, the peak wavelength is not particularly limited. The wavelength of the emission peak of the green light-emitting material in the first light-emitting unit 5a may be lower than the wavelength of the emission peak of the green light-emitting material in the second light-emitting unit 5b. In that regard, the emission of the first light-emitting unit 5a can be shifted to a lower wavelength side to increase blueness, and the white emission can be easily adjusted.

The thickness (film thickness) of each light-emitting layer 10 is not particularly limited, and may be set to be within an appropriate range from the viewpoints of adjustment of a color, and an emission efficiency or the like. For example, as the film thickness of the light-emitting layer 10, in the second light-emitting unit 5b, the film thickness of the red light-emitting layer 10R may be about 1 to 40 nm, and the film thickness of the green light-emitting layer 10G may be about 5 to 40 nm. In the first light-emitting unit 5a, the film thickness of the blue light-emitting layer 10B may be about 5 to 40 nm, and the film thickness of the green light-emitting layer 10G may be about 5 to 40 nm. The ratio of the film thicknesses is not particularly limited, and for example, in the second light-emitting unit 5b, the ratio of the film thickness of the red light-emitting layer 10R to the film thickness of the green light-emitting layer 10G may be about 1:8 to 8:1. In the first light-emitting unit 5a, the ratio of the film thickness of the blue light-emitting layer 10B to the film thickness of the green light-emitting layer 10G may be about 1:8 to 8:1. The ratio of the total thickness of the light-emitting layers 10 in the second light-emitting unit 5b to the total thickness of the light-emitting layers 10 in the first light-emitting unit 5a may be about 1:3 to 3:1. The film thickness of the intermediate layer 3 may be about 3 to 50 nm. By setting the film thicknesses as described above, the chromaticity change can be suppressed, and a higher efficiency and a longer life of the organic EL element can be achieved.

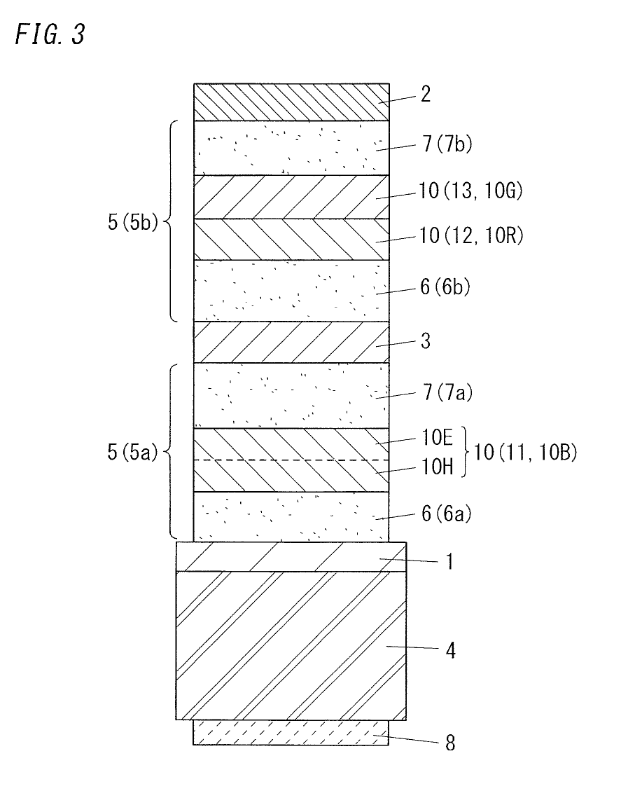

FIG. 3 shows an example of the organic EL element in the embodiment. The form of FIG. 3 is a modified example of the form of FIG. 2. One light-emitting layer 10 is provided in a first light-emitting unit 5a. The light-emitting layer 10 is a blue light-emitting layer 10B. The light-emitting layer 10 in the first light-emitting unit 5a is a first light-emitting layer 11. Herein, one light-emitting layer 10 is defined as a layer including the same dopant. In the form of FIG. 3, in one blue light-emitting layer 10B, a host material located on a positive electrode 1 side is different from a host material located on a negative electrode 2 side.

In the organic EL element, as a preferable aspect, the light-emitting layer 10 in the first light-emitting unit 5a includes a hole-transporting material as a host material on the positive electrode 1 side, and an electron-transporting material as a host material on the negative electrode 2 side. Thereby, an emission point can be easily controlled, and accordingly an element having a high light-extraction efficiency can be formed. Since the emission point is controlled, a chromaticity change can be suppressed and a stable emission color can be obtained. This is because the emission point is likely to be disposed near a boundary portion between different host materials when the host material located on the positive electrode 1 side is different from the host material located on the negative electrode 2 side.

In FIG. 3, regarding the light-emitting layers 10 of the first light-emitting unit 5a, a region including the hole-transporting material as the host material is represented by a hole-transporting region 10H, and a region including the electron-transporting material as the host material is represented by an electron-transporting region 10E. A boundary between the hole-transporting region 10H and the electron-transporting region 10E is shown by a dashed line. The hole-transporting region 10H and the electron-transporting region 10E constitute one light-emitting layer 10. A dopant included in the hole-transporting region 10H is the same as a dopant included in the electron-transporting region 10E. The hole-transporting region 10H and the electron-transporting region 10E are in contact with each other.

As shown in FIG. 3, in the blue light-emitting layer 10B, the hole-transporting region 10H and the electron-transporting region 10E are preferably provided. Emission which is highly-efficient and stable can be further obtained by controlling the emission point of blue emission.

In the form of FIG. 1, the second light-emitting layer 12 may be the blue light-emitting layers 10B. In FIG. 1, a green light-emitting layer 10G in the second light-emitting layer 12 is substituted with the blue light-emitting layer 10B. Since the light-emitting layer 10 is a layer having the same dopant from the definition of this disclosure, in this case, a dopant of the blue light-emitting layer 10B defined as the first light-emitting layer 11 may be different from a dopant of the blue light-emitting layer 10B defined as the second light-emitting layer 12. In this case, it is preferable that the host material for the first light-emitting layer 11 is the hole-transporting material, and the host material for the second light-emitting layer 12 is the electron-transporting material. Also in this case, it can be said that the first light-emitting unit 5a includes the light-emitting layers 10B which include the hole-transporting material as the host material on the positive electrode 1 side, and the electron-transporting material as the host material on the negative electrode 2 side. In the stacked structure of the plurality of blue light-emitting layers 10B, the host materials are different. Also in this case, a light-extraction property can be improved, the chromaticity change can be suppressed, and the stable emission color can be further obtained.

In the form of FIG. 1, the host material for the blue light-emitting layer 10B defined as the first light-emitting layer 11 may be the hole-transporting material, and the host material for the green light-emitting layer 10G defined as the second light-emitting layer 12 may be the electron-transporting material. Also in this case, it can be said that the first light-emitting unit 5a includes the light-emitting layers 10B which include the hole-transporting material as the host material on the positive electrode 1 side, and the electron-transporting material as the host material on the negative electrode 2 side.

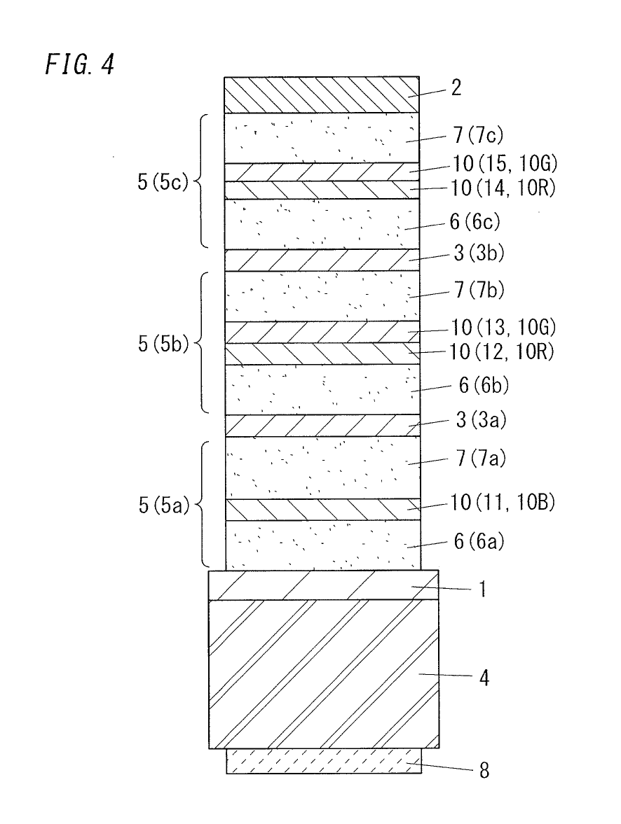

FIG. 4 shows an example of the organic EL element in the embodiment. In the form of FIG. 4, a light-emitting unit 5 (third light-emitting unit 5c) is further provided in the form of FIG. 2. That is, three light-emitting units 5 are provided. This multi-unit structure can be referred to as a three-stage multi-unit (also referred to as a “three-stage unit”). The same reference numerals are used to denote the same configurations as those of the above-mentioned form.

In a preferable aspect, the organic EL element includes a first intermediate layer 3a and a second intermediate layer 3b as an intermediate layer 3. The organic EL element further includes the third light-emitting unit 5c. The first intermediate layer 3a corresponds to the intermediate layer 3 described in the above-mentioned form, and is disposed between a first light-emitting unit 5a and a second light-emitting unit 5b. The first light-emitting unit 5a and the second light-emitting unit 5b are stacked with the first intermediate layer 3a interposed between the first light-emitting unit 5a and the second light-emitting unit 5b. The third light-emitting unit 5c is stacked on the second light-emitting unit 5b with the second intermediate layer 3b interposed between the third light-emitting unit 5c and the second light-emitting unit 5b. In the organic EL element, the first light-emitting unit 5a, the first intermediate layer 3a, the second light-emitting unit 5b, the second intermediate layer 3b, and the third light-emitting unit 5c are sequentially stacked from a positive electrode 1 side. The three-stage unit suppresses a chromaticity change and easily emits light having a stable color. The three-stage unit can increase a variation of an emission color.

In the organic EL element of FIG. 4, the configurations of the first light-emitting unit 5a and the second light-emitting unit 5b may be the same as those of the form of FIG. 2. That is, the first light-emitting unit 5a may have one light-emitting layer 10, and the light-emitting layer 10 (first light-emitting layer 11) may be a blue light-emitting layer 10B. The second light-emitting unit 5b may have a stacked structure in which a red light-emitting layer 10R and a green light-emitting layer 10G are stacked. Of course, as a modified example, the number of the light-emitting layers 10 of the first light-emitting unit 5a may be 2 or more in the organic EL element as in the form of FIG. 1. In that regard, the first light-emitting unit 5a may have a stacked structure of the blue light-emitting layer 10B and the green light-emitting layer 10G. In short, in FIG. 4, as a representative example of the three-stage unit, the second intermediate layer 3b and the third light-emitting unit 5c are the further provided. Therefore, the present invention is not limited to the layer configuration of the form of FIG. 4 within the intent of the present invention.

When the organic EL element includes the third light-emitting unit 5c, the third light-emitting unit 5c preferably has a stacked structure of the light-emitting layers 10 in which a red light-emitting layer 10R including a red light-emitting material and a green light-emitting layer 10G including a green light-emitting material are stacked. Thereby, emission having a stable color can be likely to be provided. Furthermore, in the third light-emitting unit 5c, preferably, one of the red light-emitting layer 10R and the green light-emitting layer 10G is closer to the positive electrode 1 than the other of the red light-emitting layer 10R and the green light-emitting layer 10G, and includes a hole-transporting material as a host material. Furthermore, in the third light-emitting unit 5c, preferably, the other of the red light-emitting layer 10R and the green light-emitting layer 10G is closer to the negative electrode 2 than the one of the red light-emitting layer 10R and the green light-emitting layer 10G, and includes an electron-transporting material as a host material. It can be understood that the third light-emitting unit 5c has the same structure as that of the second light-emitting unit 5b. The structure can improve a light-extraction property, suppress a chromaticity change, and provide stable emission. The reason is the same as the reason described in the second light-emitting unit 5b. In the three-stage multi-unit structure, both the second light-emitting unit 5b and the third light-emitting unit 5c have the above-mentioned structure, which can significantly achieve stabilization of a color and an improvement in a color rendering property.

The material in the second light-emitting unit 5b may be the same as the material in the third light-emitting unit 5c. Thereby, since the number of the materials can be decreased, the organic EL element can be easily manufactured. However, the film thicknesses of the internal layers may be changed in order to optimize an emission property. Interferences, emission intensities, and emission points or the like are controlled by adjusting the film thicknesses, which can provide a more advantageous structure. Of course, the film thicknesses of the internal layers may be the same.

In the third light-emitting unit 5c, a third hole transport layer 6c as a hole transport layer 6 is disposed on a surface of the light-emitting layer 10 facing the positive electrode 1. A third electron transport layer 7c as an electron transport layer 7 is disposed on a surface of the light-emitting layer 10 facing the negative electrode 2. The two light-emitting layers 10 in the third light-emitting unit 5c are numbered as a fourth light-emitting layer 14 and a fifth light-emitting layer 15 from the positive electrode 1 side.

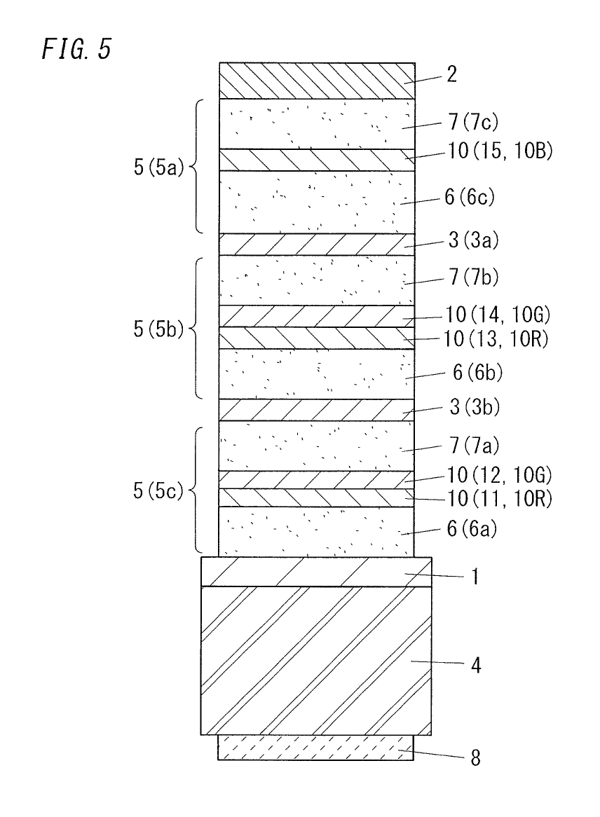

FIG. 5 shows an example of the organic EL element in the embodiment. The form of FIG. 5 is a modified example of the form of FIG. 4. The organic EL element of FIG. 5 is the same as that in the form of FIG. 4 in that the organic EL element includes a three-stage unit. Disposition of light-emitting units 5 in the organic EL element is different from that in the form of FIG. 4. In the form of FIG. 5, a first light-emitting unit 5a, a second light-emitting unit 5b, and a third light-emitting unit 5c are disposed in this order from a negative electrode 2 side. That is, a plurality of light-emitting units 5 are disposed in a reverse order to the form of FIG. 4. The same reference numerals are used to denote the same configurations as those in the above-mentioned form. A light-emitting layer 10, a hole transport layer 6, and an electron transport layer 7 (first light-emitting layer 11 to fifth light-emitting layer 15, first hole transport layer 6a to third hole transport layer 6c, first electron transport layer 7a to third electron transport layer 7c) are numbered as described above, and will be understood. In short, the layers are numbered from a positive electrode 1 side.

In the organic EL element, one of the positive electrode 1 and the negative electrode 2 may be a reflective electrode. In the case where the negative electrode 2 is the reflective electrode, the organic EL element of FIG. 5 has an advantageous structure. In the form of FIG. 5, the first light-emitting unit 5a is disposed closest to the reflective electrode among the plurality of light-emitting units 5. The first light-emitting unit 5a is a light-emitting unit 5 including a blue light-emitting layer 10B. Blue emission is light having a shorter wavelength than that of the other color, and is apt to be subject to the influence of interference. The first light-emitting unit 5a providing blue emission is disposed closest to the reflective electrode, and thereby an interference condition is easily set to a condition suitable for blue emission merely by performing film thickness adjustment in the first light-emitting unit 5a. Therefore, the blue emission can be effectively taken out. Accordingly, there can be easily provided an organic EL element which has a high light-extraction property, suppresses a chromaticity change, and provides a stable emission color.

Herein, in FIGS. 4 and 5, the third light-emitting unit 5c is provided. In the case where the organic EL element includes the third light-emitting unit 5c, a preferable aspect of the second light-emitting unit 5b may be applied to a preferable aspect of the third light-emitting unit 5c. The reason is the same as the reason described in the second light-emitting unit 5b. For example, a red light-emitting material and a green light-emitting material in the third light-emitting unit 5c are preferably phosphorescent light-emitting materials. For example, a difference between peak wavelengths of the red light-emitting material and the green light-emitting material in the third light-emitting unit 5c is preferably 75 nm or less. For example, the peak wavelength of the red light-emitting material in the third light-emitting unit 5c is preferably 610 nm or more.

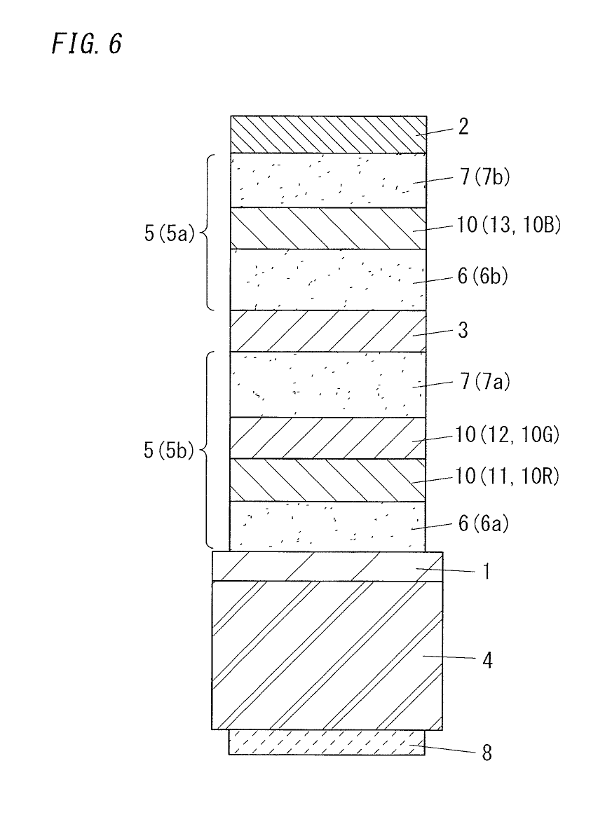

FIG. 6 shows an example of the organic EL element in the embodiment. The form of FIG. 6 is a modified example of the form of FIG. 2, and is an example in which the idea of the form of FIG. 5 is applied to a two-stage unit. In the organic EL element of FIG. 6, a first light-emitting unit 5a is disposed on a side of a negative electrode 2 which is a reflective electrode in the two-stage unit. Also in this form, a blue light-emitting layer 10B is disposed closer to the reflective electrode as in the form of FIG. 5, which can provide a stable emission color.

In each of above-mentioned forms, there has been described the organic EL element having a structure in which the positive electrode 1 is formed on the surface of the substrate 4, and light is taken out from the substrate 4 side. The structure of the organic EL element is not limited to such a structure. For example, the organic EL element may have the following structure: a negative electrode 2 is formed on the surface of a substrate 4; a positive electrode 1 is formed on a side of a plurality of light-emitting units 5 opposite to the substrate 4; and light is taken out from the substrate 4. Herein, this structure is referred to as a reverse layer bottom emission structure. For example, the organic EL element may have the following structure: a negative electrode 2 is formed on the surface of a substrate 4; a positive electrode 1 is formed on an opposite side of a plurality of light-emitting units 5 from the substrate 4; and light is taken out from a side opposite to the substrate 4 (i.e., from positive electrode 1 side). Herein, this structure is referred to as a reverse layer top emission structure. For example, the organic EL element may have the following structure: a positive electrode 1 is formed on the surface of a substrate 4; a negative electrode 2 is formed on an opposite side of a plurality of light-emitting units 5 from the substrate 4; and light is taken out from a side opposite to the substrate 4 (i.e., from negative electrode 2 side). Herein, this structure is referred to as a forward layer top emission structure. It would be understood that the structure of the organic EL element in each of the described forms is referred to as a forward layer bottom emission structure. Thus, the organic EL element has variations of light-extraction directions, and positive and negative electrodes. In short, the electrode located on the side opposite to the light-extraction side is preferably the reflective electrode. In that regard, the first light-emitting unit 5a is preferably disposed closest to the reflective electrode.

Next, material examples of the layers included in the organic EL element will be described. Materials to be described later are examples, and are not limited to the material examples. The following material examples can be applied to any of the above-mentioned forms. The material examples can be applied also to conceptual modified examples of the above-mentioned forms.

As a host material for the light-emitting layer 10, CBP, CzTT, TCTA, mCP, and CDBP or the like can be used. As the host material for the light-emitting layer 10, Alq₃, ADN, and BDAF or the like can also be used. As the host material for the light-emitting layer 10, TBADN, ADN, and BDAF or the like can also be used. As the host material for the light-emitting layer 10, DPVBi or the like can be used. Examples of the hole-transporting host material include an amine compound. Specific examples of the hole-transporting host material include TCTA, TAPC, and BSB. Examples of the electron-transporting host material include a triazole derivative, a metal complex, an oxadiazole derivative, and a silole derivative. Specific examples of the electron-transporting host material include TAZ, BPen, and OXD.

As an emission dopant providing phosphorescent green, Bt₂Ir(acac), Ir(ppy)₃, Ir(ppy)₂(acac), and Ir(mppy)₃ or the like can be used. As an emission dopant providing phosphorescent red, Btp₂Ir(acac), Ir(piq)₃, and PtOEP or the like can be used. As an emission dopant providing phosphorescent green, TPA, C545T, DMQA, coumarin6, and rubrene or the like can be used. As an emission dopant providing fluorescent blue, BCzVBi, TBP, and perylene or the like can be used. As a charge-transfer auxiliary dopant, NPD, TPD, and Spiro-TAD or the like can be used. The doping concentration of the dopant is not particularly limited, and can be be within a range of 1 to 40 mass %, and preferably 1 to 20 mass %.

As the hole transport layer 6, TPD, NPD, TPAC, and DTASi or the like can be used. The material for the hole transport layer 6 can also be used as the hole-transporting host material in the light-emitting layer 10.

As the electron transport layer 7, BCP, TAZ, BAlq, Alq₃, OXD7, and PBD or the like can be used. The material for the electron transport layer 7 can also be used as the electron-transporting host material in the light-emitting layer 10.

When a hole injection layer is provided, CuPc, MTDATA, and TiOPC or the like can be used as the hole injection layer.

When an electron injection layer is provided, as the electron injection layer, there can be used a layer doped with a fluoride, oxide, or carbonate of an alkali metal or alkaline earth metal (such as LiF, Li₂O, MgO, or Li₂CO₃); or an organic material layer doped with an alkali metal or alkaline earth metal (such as lithium, sodium, cesium, or calcium).

As the intermediate layer 3, there can be used BCP:Li, ITO, NPD:MoO₃, and Liq:Al or the like. For example, the intermediate layer 3 may have a two-layer configuration in which a first layer made of BCP:Li is disposed on the positive electrode 1 side, and a second layer made of ITO is disposed on the negative electrode 2 side.

Among the above-mentioned materials,

CBP represents 4,4′-N,N′-dicarbazolebiphenyl;

DPVBi represents 4,4′-Bis(2,2-diphenylvinyl)-1,1′-biphenyl;

Alq₃ represents tris(8-oxoquinoline)aluminum(III);

TBADN represents 2-t-butyl-9,10-di(2-naphthyl)anthracene;

Ir(ppy)₃ represents factris(2-phenylpyridine)iridium;

Ir(piq)₃ represents Tris[1-phenylisoquinolinato-C2,N]iridium(III);

Bt₂Ir(acac) represents bis(2-phenyl benzothiozola-to-N,C2′)iridium(acetylacetonate);

Btp₂Ir(acac) represents bis-(3-(2-(2-pyridyl)benzothienyl)mono-acetylacetonate)iridium (III);

TPA represents 9,10-Bis[phenyl(m-tolyl)-amino]anthracene;

BCzVBi represents 4,4′-Bis(9-ethyl-3-carbazovinylene)-1,1′-biphenyl;

C545T is coumarin C545T, and represents 10-2-(benzothiazolyl)-2,3,6,7-tetrahydro-1,1,7,7-tetramethyl-1H,5H,11H-(1)benzopyropyrano(6,7-8-ij)quinolizin-11-one;

TBP represents 1-tert-butyl-perylene;

NPD represents 4,4′-bis[N-(naphtyl)-N-phenyl-amino]biphenyl;

BCP represents 2,9-dimethyl-4,7-diphenyl-1,10-phenanthrolin;

CuPc represents copper phthalocyanine; and

TPD represents N,N′-bis(3-methylphenyl)-(1,1′-biphenyl-4,4′-diamine.

The organic EL element may be obtained by stacking the layers using any of the above-mentioned materials. A vacuum evaporation method, a sputtering method, or an applying method or the like may be used as a stacking method.

The organic EL element is on the premise that it provides white emission. Also in organic EL elements other than the organic EL element providing white emission, the layer configuration described above can serve as an advantageous structure for an improvement in an emission efficiency and stability of an emission color. That is, the organic EL element providing emission of color other than white has the following configuration. The organic EL element includes a positive electrode, a negative electrode, a first light-emitting unit including at least one light-emitting layer, a second light-emitting unit including two or more light-emitting layers, and an intermediate layer. The organic EL element has a multi-unit structure in which the first light-emitting unit and the second light-emitting unit are stacked with the intermediate layer interposed between the first light-emitting unit and the second light-emitting unit. The multi-unit structure is interposed between the positive electrode and the negative electrode. The at least one light-emitting layer of the first light-emitting unit includes a blue light-emitting material. The second light-emitting unit has a stacked structure of the two or more light-emitting layers in which a red light-emitting layer including a red light-emitting material and a green light-emitting layer including a green light-emitting material are stacked. In the second light-emitting unit, one of the red light-emitting layer and the green light-emitting layer is closer to the positive electrode than the other of the red light-emitting layer and the green light-emitting layer, and includes a hole-transporting material as a host material. In the second light-emitting unit, the other of the red light-emitting layer and the green light-emitting layer is closer to the negative electrode than the one of the red light-emitting layer and the green light-emitting layer, and includes an electron-transporting material as a host material. A preferable aspect of the organic EL element providing emission of color other than white is the same as that of the organic EL element providing white emission, and is as described above. The emission color of the organic EL element providing emission of color other than white may be a color selected from blue, green, red, yellow, and orange or the like.

The organic EL element is on the premise that the second light-emitting unit includes the red light-emitting layer and the green light-emitting layer. However, even when the second light-emitting unit does not include both the red light-emitting layer and the green light-emitting layer, the configuration described above can serve as an advantageous structure for an improvement in an emission efficiency, and stabilization of an emission color. That is, the organic EL element in which the second light-emitting unit does not include the red light-emitting layer and the green light-emitting layer has the following configuration. The organic EL element includes a positive electrode, a negative electrode, a first light-emitting unit including at least one light-emitting layer, a second light-emitting unit including two or more light-emitting layers, and an intermediate layer. The organic EL element has a multi-unit structure in which the first light-emitting unit and the second light-emitting unit are stacked with the intermediate layer interposed between the first light-emitting unit and the second light-emitting unit. The multi-unit structure is interposed between the positive electrode and the negative electrode. The emission color of the organic EL element may be white, or may not be white. The light-emitting layer of the first light-emitting unit may include a blue light-emitting material, or may not include the blue light-emitting material. The second light-emitting unit has a stacked structure of the two or more light-emitting layers in which the two or more light-emitting layers are stacked. In the second light-emitting unit, one of the two or more stacked light-emitting layers is closer to the positive electrode than the other of the two or more stacked light-emitting layers, and includes a hole-transporting material as a host material. The other of the two or more stacked light-emitting layers is closer to the negative electrode than the one of the two or more stacked light-emitting layers, and includes an electron-transporting material as a host material. The emission colors of the two or more light-emitting layers in the second light-emitting unit may be selected from blue, green, and red. A preferable aspect of the organic EL element in which the second light-emitting unit does not include the red light-emitting layer and the green light-emitting layer is the same as that of the organic EL element in which the second light-emitting unit includes the red light-emitting layer and the green light-emitting layer, and is as described above. The first light-emitting unit may have a stacked structure in which two or more light-emitting layers are stacked. In that regard, in the first light-emitting unit, preferably, one of the two or more stacked light-emitting layers is closer to the positive electrode than the other of the two or more stacked light-emitting layers, and includes a hole-transporting material as a host material. Preferably, the other of the two or more stacked light-emitting layers is closer to the negative electrode than the one of the two or more light-emitting layers, and includes an electron-transporting material as a host material.

An illumination device can be provided by using the above-mentioned organic EL element. The illumination device includes the organic EL element. Thereby, the illumination device having a high light-extraction efficiency, a suppressed chromaticity change, and a stable emission color can be obtained. The illumination device may include a plurality of organic EL elements disposed in a planar form. When the plurality of organic EL elements are disposed in a planar form, the difference between the emission colors of the adjacent organic EL elements can be made unnoticeable. The illumination device may be a planar illumination body including one organic EL element. The illumination device may have a wiring structure for supplying electric power to the organic EL element. The illumination device may include a case supporting the organic EL element. The illumination device may include a plug electrically connecting the organic EL element and a power source to each other. The illumination device can have a panel like structure. Since the illumination device can have a reduced thickness, the illumination device can provide a space-saving light fixture.

### EXAMPLES

### Test 1

### Example 1

There was produced an organic EL element having a multi-unit structure having a layer configuration of FIG. 2. The number of light-emitting layers 10 of a first light-emitting unit 5a is 1. The light-emitting layer 10 is a first light-emitting layer 11.

In the element of Example 1, BCzVBi which was a fluorescent light-emitting material was used as a blue light-emitting material included in the first light-emitting unit 5a. DPVBi was used as a host material for the light-emitting layer 10 (first light-emitting layer 11, blue light-emitting layer 10B) in the first light-emitting unit 5a. The film thickness of the first light-emitting layer 11 was 20 nm. Btp₂Ir(acac) which was a phosphorescent light-emitting material was used as a red light-emitting material included in a second light-emitting unit 5b. Bt₂Ir(acac) which was a phosphorescent light-emitting material was used as a green light-emitting material included in the second light-emitting unit 5b. As a host material for a red light-emitting layer 10R (second light-emitting layer 12) in the second light-emitting unit 5b, an amine compound which was a hole-transporting material was used. A triazole derivative which was an electron-transporting material was used as a host material for a green light-emitting layer 10G (third light-emitting layer 13) in the second light-emitting unit 5b. The film thickness of the red light-emitting layer 10R (second light-emitting layer 12) was 30 nm, and the film thickness of the green light-emitting layer 10G (third light-emitting layer 13) was 40 nm. Thereby, white emission having a color temperature of 3000 K was achieved.

ITO was used for a positive electrode 1, and Al was used for a negative electrode 2. TPD was used for a hole transport layer 6. BCP was used for an electron transport layer 7. ITO was used for an intermediate layer 3.

### Example 2

In a second light-emitting unit 5b, the film thickness of a red light-emitting layer 10R (second light-emitting layer 12) was 20 nm, and the film thickness of a green light-emitting layer 10G (third light-emitting layer 13) was 40 nm. Thereby, white emission having a color temperature of 4000 K was achieved. An organic EL element was produced in the same manner as in Example 1 except for this.

### Example 3

In a second light-emitting unit 5b, the film thickness of a red light-emitting layer 10R (second light-emitting layer 12) was 10 nm, and the film thickness of a green light-emitting layer 10G (third light-emitting layer 13) was 40 nm. Thereby, white emission having a color temperature of 5000 K was achieved. An organic EL element was produced in the same manner as in Example 1 except for this.

### Example 4

In a second light-emitting unit 5b, Ir(piq)₃ was used as a red light-emitting material for a red light-emitting layer 10R (second light-emitting layer 12). The film thickness of the red light-emitting layer 10R (second light-emitting layer 12) was 30 nm, and the film thickness of a green light-emitting layer 10G (third light-emitting layer 13) was 40 nm. The concentrations of the light-emitting materials were adjusted. Thereby, white emission having a color temperature of 3000 K was achieved. An organic EL element was produced in the same manner as in Example 1 except for this.

### Example 5

In a second light-emitting unit 5b, the film thickness of a red light-emitting layer 10R (second light-emitting layer 12) was 20 nm, and the film thickness of a green light-emitting layer 10G (third light-emitting layer 13) was 40 nm. Thereby, white emission having a color temperature of 4000 K was achieved. An organic EL element was produced in the same manner as in Example 4 except for this.

### Example 6

In a second light-emitting unit 5b, the film thickness of a red light-emitting layer 10R (second light-emitting layer 12) was 10 nm, and the film thickness of a green light-emitting layer 10G (third light-emitting layer 13) was 40 nm. Thereby, white emission having a color temperature of 5000 K was achieved. An organic EL element was produced in the same manner as in Example 4 except for this.

### Example 7

There was produced an organic EL element having a multi-unit structure having a layer configuration of FIG. 1. In the element of Example 7, the number of light-emitting layers 10 of a first light-emitting unit 5a was 2 (first light-emitting layer 11 and second light-emitting layer 12) as in the layer configuration of FIG. 1.

In the element of Example 7, BCzVBi which was a fluorescent light-emitting material was used as a blue light-emitting material included in the first light-emitting unit 5a. TPA which was a fluorescent light-emitting material was used as a green light-emitting material included in the first light-emitting unit 5a. DPVBi was used as a host material for the first light-emitting layer 11 (blue light-emitting layer 10B) and the second light-emitting layer 12 (green light-emitting layer 10G) in the first light-emitting unit 5a. The film thickness of the first light-emitting layer 11 was 20 nm, and the film thickness of the second light-emitting layer 12 was 15 nm. The other materials were made to be the same as those of the element of Example 4. That is, Ir(piq)₃ which was a phosphorescent light-emitting material was used as a red light-emitting material included in a second light-emitting unit 5b. Bt₂Ir(acac) which was a phosphorescent light-emitting material was used as a green light-emitting material included in the second light-emitting unit 5b. As a host material for a red light-emitting layer 10R (third light-emitting layer 13) in the second light-emitting unit 5b, an amine compound which was a hole-transporting material was used. A triazole derivative which was an electron-transporting material was used as a host material for a green light-emitting layer 10G (fourth light-emitting layer 14) in the second light-emitting unit 5b. The film thickness of the red light-emitting layer 10R (third light-emitting layer 13) was 30 nm, and the film thickness of the green light-emitting layer 10G (fourth light-emitting layer 14) was 40 nm. Thereby, white emission having a color temperature of 3000 K was achieved. Materials for a positive electrode 1, a negative electrode 2, a hole transport layer 6, an electron transport layer 7, and an intermediate layer 3 were made the same as those in Example 1.

### Example 8

In a first light-emitting unit 5a, the film thickness of a blue light-emitting layer 10B (first light-emitting layer 11) was 25 nm, and the film thickness of a green light-emitting layer 10G (second light-emitting layer 12) was 15 nm. In a second light-emitting unit 5b, the film thickness of a red light-emitting layer 10R (third light-emitting layer 13) was 20 nm, and the film thickness of a green light-emitting layer 10G (fourth light-emitting layer 14) was 40 nm. Thereby, white emission having a color temperature of 4000 K was achieved. An organic EL element was produced in the same manner as in Example 7 except for this.

### Example 9

In a first light-emitting unit 5a, the film thickness of a blue light-emitting layer 10B (first light-emitting layer 11) was 30 nm, and the film thickness of a green light-emitting layer 10G (second light-emitting layer 12) was 10 nm. In a second light-emitting unit 5b, the film thickness of a red light-emitting layer 10R (third light-emitting layer 13) was 10 nm, and the film thickness of a green light-emitting layer 10G (fourth light-emitting layer 14) was 40 nm. Thereby, white emission having a color temperature of 5000 K was achieved. An organic EL element was produced in the same manner as in Example 7 except for this.

### Comparative Example 1

In the layer configuration of FIG. 1, there was produced an organic EL element having a multi-unit structure in which the host materials for the light-emitting layers 10 in the second light-emitting unit 5b are the same as each other.

In the element of Comparative Example 1, BCzVBi which was a fluorescent light-emitting material was used as a blue light-emitting material included in a first light-emitting unit 5a. TPA which was a fluorescent light-emitting material was used as a green light-emitting material included in the first light-emitting unit 5a. DPVBi was used as a host material for a first light-emitting layer 11 (blue light-emitting layer 10B) and a second light-emitting layer 12 (green light-emitting layer 10G) in the first light-emitting unit 5a. The film thickness of the first light-emitting layer 11 was 20 nm, and the film thickness of the second light-emitting layer 12 was 15 nm. Btp₂Ir(acac) which was a phosphorescent light-emitting material was used as a red light-emitting material included in the second light-emitting unit 5b. Ir(ppy)₃ which was a phosphorescent light-emitting material was used as a green light-emitting material included in the second light-emitting unit 5b. CBP which was a bipolar material was used as a host material for a red light-emitting layer 10R (third light-emitting layer 13) and a green light-emitting layer 10G (fourth light-emitting layer 14) in the second light-emitting unit 5b. The film thickness of the red light-emitting layer 10R (third light-emitting layer 13) was 20 nm, and the film thickness of the green light-emitting layer 10G (fourth light-emitting layer 14) was 40 nm. Thereby, white emission having a color temperature of 3000 K was achieved. The other materials were made to be the same as those of the element of Example 1. That is, materials for a positive electrode 1, a negative electrode 2, a hole transport layer 6, an electron transport layer 7, and an intermediate layer 3 were made the same as those in Example 1.

### Comparative Example 2

In a second light-emitting unit 5b, the film thickness of a red light-emitting layer 10R (third light-emitting layer 13) was 7 nm, and the film thickness of a green light-emitting layer 10G (fourth light-emitting layer 14) was 40 nm. The concentrations of light-emitting materials were adjusted. Thereby, white emission having a color temperature of 4000 K was achieved. An organic EL element was produced in the same manner as in Comparative Example 1 except for this.

### Comparative Example 3

In a second light-emitting unit 5b, the film thickness of a red light-emitting layer 10R (third light-emitting layer 13) was 2 nm, and the film thickness of a green light-emitting layer 10G (fourth light-emitting layer 14) was 40 nm. The concentrations of light-emitting materials were adjusted. Thereby, white emission having a color temperature of 5000 K was achieved. An organic EL element was produced in the same manner as in Comparative Example 1 except for this.

### Comparative Example 4

An organic EL element was produced in the same manner as in Example 7 except that CBP which was a bipolar material was used as a host material for a red light-emitting layer 10R (third light-emitting layer 13) and a green light-emitting layer 10G (fourth light-emitting layer 14) in a second light-emitting unit 5b.

### Comparative Example 5

An organic EL element was produced in the same manner as in Example 8 except that CBP which was a bipolar material was used as a host material for a red light-emitting layer 10R (third light-emitting layer 13) and a green light-emitting layer 10G (fourth light-emitting layer 14) in a second light-emitting unit 5b.

### Comparative Example 6

An organic EL element was produced in the same manner as in Example 9 except that CBP which was a bipolar material was used as a host material for a red light-emitting layer 10R (third light-emitting layer 13) and a green light-emitting layer 10G (fourth light-emitting layer 14) in a second light-emitting unit 5b.

### (Characteristics of Organic EL Elements)

Table 1 shows the characteristics of the organic EL elements obtained in the above-mentioned Examples and Comparative Examples. In Table 1, a “color variation” is shown by Δu′v′ obtained by measuring a difference in colors of the plurality of produced elements as a variation. A “color shift” is shown by Δu′v′ obtained by measuring a change in chromaticity with time (LT70). Ra represents a color rendering index, and is an average of R1 to R9. R9 represents a special color rendering index, and is an index mainly relating to red.

As shown in Table 1, each of the elements of Examples has a suppressed color variation and color shift as compared with each of the elements of Comparative Examples. Each of the elements of Examples has a high special color rendering index R9. When comparing the elements of Examples having the same configuration (Examples 7 to 9 and Comparative Examples 1 to 6), Examples 7 to 9 have Ra higher than those of the elements of Comparative Examples 1 to 6. Therefore, the organic EL elements of Examples were confirmed to have a suppressed chromaticity change and a high color rendering property.

TABLE 1

| | | Second light-emitting unit | | | |
|---|---|---|---|---|---|
| | | | | Difference between | |
| | | Host of red light- | Host of green light- | peak wavelengths | Red |
| | First light-emitting unit | emitting layer | emitting layer | of red and green | wavelength |
| Example 1 | Blue light-emitting layer | Hole transport property | Electron transport | 56 | 619 |
| | | | property | | |
| Example 2 | Blue light-emitting layer | Hole transport property | Electron transport | 56 | 619 |
| | | | property | | |
| Example 3 | Blue light-emitting layer | Hole transport property | Electron transport | 56 | 619 |
| | | | property | | |
| Example 4 | Blue light-emitting layer | Hole transport property | Electron transport | 63 | 626 |
| | | | property | | |
| Example 5 | Blue light-emitting layer | Hole transport property | Electron transport | 63 | 626 |
| | | | property | | |
| Example 6 | Blue light-emitting layer | Hole transport property | Electron transport | 63 | 626 |
| | | | property | | |
| Example 7 | Blue light-emitting layer + | Hole transport property | Electron transport | 63 | 626 |
| | green light-emitting layer | | property | | |
| Example 8 | Blue light-emitting layer + | Hole transport property | Electron transport | 63 | 626 |
| | green light-emitting layer | | property | | |
| Example 9 | Blue light-emitting layer + | Hole transport property | Electron transport | 63 | 626 |
| | green light-emitting layer | | property | | |
| Comparative Example 1 | Blue light-emitting layer + | Bipolar property | Bipolar property | 103 | 619 |
| | green light-emitting layer | | | | |
| Comparative Example 2 | Blue light-emitting layer + | Bipolar property | Bipolar property | 103 | 619 |
| | green light-emitting layer | | | | |
| Comparative Example 3 | Blue light-emitting layer + | Bipolar property | Bipolar property | 103 | 619 |
| | green light-emitting layer | | | | |
| Comparative Example 4 | Blue light-emitting layer + | Bipolar property | Bipolar property | 63 | 626 |
| | green light-emitting layer | | | | |
| Comparative Example 5 | Blue light-emitting layer + | Bipolar property | Bipolar property | 63 | 626 |
| | green light-emitting layer | | | | |
| Comparative Example 6 | Blue light-emitting layer + | Bipolar property | Bipolar property | 63 | 626 |
| | green light-emitting layer | | | | |

| | | Color | | | |
|---|---|---|---|---|---|
| | Color | variation | | | |
| | temperature | 3σ | Color shift | Ra | R9 |
| Example 1 | 3000 K | 0.0012 | 0.0036 | 83 | 46 |
| Example 2 | 4000 K | 0.0013 | 0.0035 | 81 | 44 |
| Example 3 | 5000 K | 0.0013 | 0.0036 | 81 | 48 |
| Example 4 | 3000 K | 0.0020 | 0.0041 | 85 | 68 |
| Example 5 | 4000 K | 0.0020 | 0.0041 | 83 | 65 |
| Example 6 | 5000 K | 0.0021 | 0.0041 | 84 | 65 |
| Example 7 | 3000 K | 0.0018 | 0.0038 | 92 | 70 |
| Example 8 | 4000 K | 0.0017 | 0.0039 | 91 | 67 |
| Example 9 | 5000 K | 0.0018 | 0.0039 | 90 | 59 |
| Comparative Example 1 | 3000 K | 0.0040 | 0.0072 | 89 | 42 |
| Comparative Example 2 | 4000 K | 0.0046 | 0.0081 | 88 | 40 |
| Comparative Example 3 | 5000 K | 0.0050 | 0.0099 | 89 | 43 |
| Comparative Example 4 | 3000 K | 0.0053 | 0.0088 | 89 | 66 |
| Comparative Example 5 | 4000 K | 0.0054 | 0.0097 | 89 | 65 |
| Comparative Example 6 | 5000 K | 0.0058 | 0.0110 | 88 | 55 |

### Test 2

There was produced an organic EL element having a layer configuration of FIG. 3, to attempt optimization of a light-emitting layer 10 in a first light-emitting unit 5a.

### Examples 10 to 12

In each of Examples 1 to 3, a light-emitting layer 10 (first light-emitting layer 11, blue light-emitting layer 10B) of a first light-emitting unit 5a included two regions (hole-transporting region 10H, electron-transporting region 10E) (see FIG. 3). An amine compound which was a hole-transporting material was used as a host material in the hole-transporting region 10H. DPVBi which was an electron-transporting material was used in the electron-transporting region 10E. The thickness of the hole-transporting region 10H was 10 nm, and the thickness of the electron-transporting region 10E was 10 nm. The whole thickness of the light-emitting layer 10 of the first light-emitting unit 5a was 20 nm.

In Example 10, an organic EL element having a color temperature of 3000 K was produced in the same manner as in Example 1 except the above.

In Example 11, an organic EL element having a color temperature of 4000 K was produced in the same manner as in Example 2 except the above.

In Example 12, an organic EL element having a color temperature of 5000 K was produced in the same manner as in Example 3 except the above.

### (Characteristics of Organic EL Elements)

The characteristics of the organic EL elements of Examples 10 to 12 are shown in Table 2. Evaluation items in Table 2 are the same as those of Table 1.

As shown in Table 2, each of the elements of Examples 10 to 12 has a suppressed color variation and color shift, a high special color rendering index R9, and high Ra. Each of the elements of Examples 10 to 12 has a further suppressed color shift as compared with each of the elements of Examples 1 to 3 when comparing the elements of Examples having the same color temperatures. Therefore, the host material for the blue light-emitting layer was optimized, and the organic EL elements of Examples 10 to 12 were confirmed to have a suppressed color shift and provide a stable emission color.

TABLE 2

| | First light-emitting unit | | | Second light-emitting unit | | | |
|---|---|---|---|---|---|---|---|
| | | Host on | Host on | | | Difference | |
| | | positive | positive | Host of red | Host of green | between peak | |
| | Emission | electrode | electrode | light-emitting | light-emitting | wavelengths of | Red |
| | color | side | side | layer | layer | red and green | wavelength |
| Example | Blue light- | Hole | Electron | Hole transport | Electron | 56 | 619 |
| 10 | emitting layer | transport | transport | property | transport | | |
| | | property | property | | property | | |
| Example | Blue light- | Hole | Electron | Hole transport | Electron | 56 | 619 |
| 11 | emitting layer | transport | transport | property | transport | | |
| | | property | property | | property | | |
| Example | Blue light- | Hole | Electron | Hole transport | Electron | 56 | 619 |
| 12 | emitting layer | transport | transport | property | transport | | |
| | | property | property | | property | | |

| | | Color | | | |
|---|---|---|---|---|---|
| | Color | variation | | | |
| | temperature | 3σ | Color shift | Ra | R9 |
| Example | 3000 K | 0.0012 | 0.0029 | 83 | 46 |
| 10 | | | | | |
| Example | 4000 K | 0.0013 | 0.0028 | 81 | 44 |
| 11 | | | | | |
| Example | 5000 K | 0.0013 | 0.0028 | 81 | 48 |
| 12 | | | | | |

### Test 3

There was produced an organic EL element having a layer configuration shown in FIGS. 4 and 5, and the organic EL element having a three-stage unit structure was examined.

### Example 13

There was produced an organic EL element having a multi-unit structure having a layer configuration of FIG. 4.

In the element of Example 13, BCzVBi which was a fluorescent light-emitting material was used as a blue light-emitting material included in a first light-emitting unit 5a. DPVBi was used as a host material for a light-emitting layer 10 (first light-emitting layer 11, blue light-emitting layer 10B) in the first light-emitting unit 5a. The film thickness of the first light-emitting layer 11 was 20 nm. Btp₂Ir(acac) which was a phosphorescent light-emitting material was used as a red light-emitting material included in a second light-emitting unit 5b and a third light-emitting unit 5c. Bt₂Ir(acac) which was a phosphorescent light-emitting material was used as a green light-emitting material included in the second light-emitting unit 5b and the third light-emitting unit 5c. As a host material for red light-emitting layers 10R (second light-emitting layer 12 and fourth light-emitting layer 14) in the second light-emitting unit 5b and the third light-emitting unit 5c, an amine compound which was a hole-transporting material was used. A triazole derivative which was an electron-transporting material was used as a host material for green light-emitting layers 10G (third light-emitting layer 13 and fifth light-emitting layer 15) in the second light-emitting unit 5b and the third light-emitting unit 5c. The film thicknesses of the red light-emitting layers 10R (second light-emitting layer 12 and fourth light-emitting layer 14) in the second light-emitting unit 5b and the third light-emitting unit 5c were 15 nm. The film thicknesses of the green light-emitting layers 10G (third light-emitting layer 13 and fifth light-emitting layer 15) in the second light-emitting unit 5b and the third light-emitting unit 5c were 40 nm. Thereby, white emission having a color temperature of 2800 K was achieved.

ITO was used for a positive electrode 1, and Al was used for a negative electrode 2. TPD was used for a hole transport layer 6. BCP was used for an electron transport layer 7. ITO was used for a first intermediate layer 3a and a second intermediate layer 3b.

### Comparative Example 7

In Example 13, CBP which was a bipolar material was used as a host material for a red light-emitting layer 10R (second light-emitting layer 12, fourth light-emitting layer 14) in a second light-emitting unit 5b and a third light-emitting unit 5c. CBP which was a bipolar material was used as a host material for a green light-emitting layer 10G (third light-emitting layer 13, fifth light-emitting layer 15) in the second light-emitting unit 5b and the third light-emitting unit 5c. An organic EL element of Comparative Example 7 having a color temperature of 2800 K was produced in the same manner as in Example 13 except for this.

### Example 14

There was produced an organic EL element having a multi-unit structure having a layer configuration of FIG. 5. That is, in Example 14, a first light-emitting unit 5a including a blue light-emitting layer 10B was disposed on a side of a negative electrode 2 which was a reflective electrode.

In the element of Example 14, materials for the first light-emitting unit 5a, a second light-emitting unit 5b, and a third light-emitting unit 5c, and the film thickness of each light-emitting layer were made to be the same as those of Example 13, and disposition of a light-emitting unit 5 was changed. The organic EL element of Example 14 having a color temperature of 2800 K was produced in the same manner as in Example 13 except for this.

### (Characteristics of Organic EL Elements)

The characteristics of the organic EL elements of Examples 13 and 14 and Comparative Example 7 are shown in Table 3. Light-extraction efficiencies are described in Table 3. The other evaluation items in Table 3 are the same as those of Table 1. The light-extraction efficiency is calculated from an amount of energy of light taken out to a current applied to the element. In Table 3, when an efficiency of Example 14 is defined as a basis (1.00), the light-extraction efficiencies are described as relative values on the basis.

As shown in Table 3, the element of Example 13 has a suppressed color variation and color shift, and high Ra, as compared with Comparative Example 7. The element of Example 13 has a high special color rendering index R9. The element of Example 13 has also an increased light-extraction efficiency. Therefore, it is found that the configuration of the organic EL element is effective also in the structure of the three-stage unit.

When comparing Example 13 with Example 14, the light-extraction efficiency of Example 14 is higher than that of Example 13. In addition, Example 14 has a further suppressed color variation and color shift compared with Example 13. This shows that it is effective to dispose the light-emitting unit including the blue light-emitting layer near the reflective electrode.

TABLE 3

| | | | Second light-emitting unit | | | |
|---|---|---|---|---|---|---|
| | | | | | Difference | |
| | | | Host of red | Host of green | between peak | |
| | First light-emitting unit | | light-emitting | light-emitting | wavelengths of | Red |
| | Emission color | Disposition | layer | layer | red and green | wavelength |
| Example 13 | Blue light- | Positive | Hole transport | Electron | 56 | 619 |
| | emitting layer | electrode side | property | transport | | |
| | | | | property | | |
| Comparative | Blue light- | Positive | Bipolar | Bipolar | 103 | 619 |
| Exampl 7 | emitting layer | electrode side | property | property | | |
| Example 14 | Blue light- | Negative | Hole transport | Electron | 56 | 619 |
| | emitting layer | electrode side | property | transport | | |
| | | (reflective | | property | | |
| | | electrode side) | | | | |

| | | | Color | | | | Light- |
|---|---|---|---|---|---|---|---|
| | Third light- | Color | variation | | | | extraction |
| | emitting unit | temperature | 3σ | Color shift | Ra | R9 | efficiency |
| Example 13 | The same as | 2800 K | 0.0013 | 0.0037 | 80 | 44 | 0.91 |
| | second light- | | | | | | |
| | emitting unit | | | | | | |
| Comparative | The same as | 2800 K | 0.0051 | 0.0088 | 79 | 44 | 0.90 |
| Exampl 7 | second light- | | | | | | |
| | emitting unit | | | | | | |
| Example 14 | The same as | 2800 K | 0.0012 | 0.0036 | 80 | 44 | 1.00 |
| | second light- | | | | | | |
| | emitting unit | | | | | | |

### REFERENCE SIGNS LIST

1 Positive electrode
2 Negative electrode
3 Intermediate layer
4 Substrate
5 Light-emitting unit
5a First light-emitting unit
5b Second light-emitting unit
5c Third light-emitting unit
6 Hole transport layer
7 Electron transport layer
8 Light-extraction layer
10 light-emitting layer
10G Green light-emitting layer
10R Red light-emitting layer
10B Blue light-emitting layer

1. An organic electroluminescence element comprising:
a positive electrode;
a negative electrode;
a first light-emitting unit including at least one light-emitting layer;
a second light-emitting unit including two or more light-emitting layers; and
an intermediate layer,
the organic electroluminescence element having a multi-unit structure in which the first light-emitting unit and the second light-emitting unit are stacked with the intermediate layer interposed between the first light-emitting unit and the second light-emitting unit, the multi-unit structure being interposed between the positive electrode and the negative electrode,
the organic electroluminescence element providing a white emission color,
the at least one light-emitting layer of the first light-emitting unit including a blue light-emitting material,
the second light-emitting unit having a stacked structure of the two or more light-emitting layers in which a red light-emitting layer including a red light-emitting material and a green light-emitting layer including a green light-emitting material are stacked,
one of the red light-emitting layer and the green light-emitting layer of the second light-emitting unit being closer to the positive electrode than an other of the red light-emitting layer and the green light-emitting layer of the second light-emitting unit, and including a hole-transporting material as a host material,
the other of the red light-emitting layer and the green light-emitting layer of the second light-emitting unit being closer to the negative electrode than the one of the red light-emitting layer and the green light-emitting layer of the second light-emitting unit, and including an electron-transporting material as a host material.

2. The organic electroluminescence element according to claim 1, wherein
the red light-emitting material and the green light-emitting material in the second light-emitting unit are phosphorescent light-emitting materials.

3. The organic electroluminescence element according to claim 1, wherein
the first light-emitting unit includes a blue fluorescent light-emitting material and a green fluorescent light-emitting material.

4. The organic electroluminescence element according to claim 1, wherein
a difference between peak wavelengths of the red light-emitting material and the green light-emitting material in the second light-emitting unit is 75 nm or less.

5. The organic electroluminescence element according to claim 1, wherein
a peak wavelength of the red light-emitting material in the second light-emitting unit is 610 nm or more.

6. The organic electroluminescence element according to claim 1, wherein
the at least one light-emitting layer of the first light-emitting unit includes a hole-transporting material as a host material on a side of the positive electrode and an electron-transporting material as a host material on a side of the negative electrode.

7. The organic electroluminescence element according to claim 1, wherein
the intermediate layer is a first intermediate layer,
the organic electroluminescence element further comprises:
a second intermediate layer; and
a third light-emitting unit including two or more light-emitting layers,
the third light-emitting unit is stacked on the first light-emitting unit or the second light-emitting unit with the second intermediate layer interposed between the third light-emitting unit and the first light-emitting unit or the second light-emitting unit,
the third light-emitting unit have a stacked structure of the two or more light-emitting layers in which a red light-emitting layer including a red light-emitting material and a green light-emitting layer including a green light-emitting material are stacked,
one of the red light-emitting layer and the green light-emitting layer of the third light-emitting unit is closer to the positive electrode than an other of the red light-emitting layer and the green light-emitting layer of the third light-emitting unit, and includes a hole-transporting material as a host material, and
the other of the red light-emitting layer and the green light-emitting layer of the third light-emitting unit is closer to the negative electrode than the one of the red light-emitting layer and the green light-emitting layer of the third light-emitting unit, and includes an electron-transporting material as a host material.

8. The organic electroluminescence element according to claim 1, wherein
one of the positive electrode and the negative electrode is a reflective electrode; and
the first light-emitting unit is disposed closest to the reflective electrode among a plurality of light-emitting units that include at least the first light-emitting unit and the second light-emitting unit.

9. An illumination device comprising the organic electroluminescence element according to claim 1.

10. The organic electroluminescence element according to claim 2, wherein
the first light-emitting unit includes a blue fluorescent light-emitting material and a green fluorescent light-emitting material.

11. The organic electroluminescence element according to claim 2, wherein
a difference between peak wavelengths of the red light-emitting material and the green light-emitting material in the second light-emitting unit is 75 nm or less.

12. The organic electroluminescence element according to claim 3, wherein
the at least one light-emitting layer of the first light-emitting unit includes a hole-transporting material as a host material on a side of the positive electrode and an electron-transporting material as a host material on a side of the negative electrode.

13. The organic electroluminescence element according to claim 7, wherein
one of the positive electrode and the negative electrode is a reflective electrode; and
the first light-emitting unit is disposed closest to the reflective electrode among a plurality of light-emitting units that include at least the first light-emitting unit, the second light-emitting unit and the third light-emitting unit.

14. An illumination device comprising the organic electroluminescence element according to claim 7.
